(19) United States
(12) Patent Application Publication
(10) Pub. No.: US 2022/0237099 A1
(43) Pub. Date: Jul. 28, 2022

(54) SERVICE SPECIFYING METHOD AND NON-TRANSITORY COMPUTER-READABLE MEDIUM

(71) Applicant: FUJITSU LIMITED, Kawasaki-shi (JP)

(72) Inventors: Takashi Shiraishi, Atsugi (JP); Reiko Kondo, Yamato (JP); Hitoshi UENO, Kawasaki (JP)

(73) Assignee: FUJITSU LIMITED, Kawasaki-shi (JP)

(21) Appl. No.: 17/492,913

(22) Filed: Oct. 4, 2021

(30) Foreign Application Priority Data
Jan. 27, 2021 (JP) 2021-011204

(51) Int. Cl. G06F 11/34; G06F 30/27; G06F 11/30

(52) U.S. Cl. CPC G06F 11/3447; G06F 11/3006; G06F 11/3457; G06F 30/27

(57) ABSTRACT

A service specifying method for causing a computer to execute a process. The process includes acquiring a parameter indicating a load of a resource used by a plurality of services for each of the plurality of services, estimating a performance of each service for each of a plurality of the services by using an estimation model that estimates the performance of the each service from the parameter related to the each service, the estimation model being provided for each of the plurality of services, and specifying, among the plurality of services, a service whose performance is deteriorated due to a failure of the resource based on the estimated performance.

### CROSS-REFERENCE TO RELATED APPLICATION

This application is based upon and claims the benefit of priority of the prior Japanese Patent Application No. 2021-011204 filed on Jan. 27, 2021, the entire contents of which are incorporated herein by reference.

### FIELD

A certain aspect of the embodiments is related to a service specifying method and a non-transitory computer-readable medium.

### BACKGROUND

With the development of cloud computing technology, microservice architecture that combines a plurality of application programs to provide a single service is widespread. In the microservice architecture, when an abnormality occurs in the infrastructure such as a container or a virtual machine that executes each application program, the service built by these application programs is also affected by deterioration of response time and the like.

Therefore, a service administrator identifies a service whose performance is deteriorated due to the failure of the infrastructure, and implements measures such as scaling out the container executing the service.

However, when a plurality of services are executed on the infrastructure, it is not easy to specify the service whose performance is deteriorated due to the failure of the infrastructure among these services. Note that the technique related to the present disclosure is disclosed in Japanese Laid-open Patent Publication No. 2018-205811.

### SUMMARY

According to an aspect of the present disclosure, there is provided a service specifying method for causing a computer to execute a process, the process including: acquiring a parameter indicating a load of a resource used by a plurality of services for each of the plurality of services; estimating a performance of each service for each of a plurality of the services by using an estimation model that estimates the performance of the each service from the parameter related to the each service, the estimation model being provided for each of the plurality of services; and specifying, among the plurality of services, a service whose performance is deteriorated due to a failure of the resource based on the estimated performance.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of infrastructure for realizing a microservice architecture;

FIG. 2 is a schematic diagram of the infrastructure when a failure occurs;

FIG. 3 is a diagram illustrating an example of a configuration graph;

FIG. 4 is a schematic diagram for explaining an estimation model;

FIG. 5 is a schematic diagram illustrating that an estimation accuracy deteriorates;

FIG. 6 is a block diagram of a system according to a first embodiment;

FIG. 7 is a schematic diagram of a virtualized environment realized by a physical server according to the first embodiment.

FIG. 8 is a schematic diagram of a service realized by the system according to the first embodiment;

FIG. 9 is a schematic diagram illustrating a service specifying method according to the first embodiment;

FIG. 10 is a diagram illustrating an example of parameters according to the first embodiment;

FIGS. 11A to 11C are schematic diagrams illustrating a method of determining whether a failure occurs in a resource in the first embodiment;

FIG. 12 is a schematic diagram illustrating a process performed by a service specifying device when it is determined that the failure occurs in the resource in the first embodiment;

FIG. 13 is a schematic diagram illustrating another display example of a display device according to the first embodiment;

FIG. 14 is a block diagram illustrating functional configuration of the service specifying device according to the first embodiment;

FIG. 15 is a schematic diagram illustrating deployment destinations of softwares in the first embodiment;

FIGS. 16A and 16B are schematic diagrams (part 1) of a generating method of a configuration graph according to the first embodiment;

FIGS. 17A and 17B are schematic diagrams (part 2) of the generating method of the configuration graph according to the first embodiment;

FIGS. 18A and 18B are schematic diagrams (part 3) of the generating method of the configuration graph according to the first embodiment;

FIG. 19 is a flowchart of the service specifying method according to the first embodiment;

FIG. 20A is a schematic diagram illustrating the service before scale-out according to the second embodiment;

FIG. 20B is a schematic diagram illustrating the service after scale-out according to the second embodiment;

FIG. 21 is a schematic diagram for explaining the service specifying method according to the second embodiment;

FIG. 22 is a schematic diagram of a network configuration graph used to generate a network performance estimation model according to the second embodiment;

FIG. 23 is a schematic diagram of the network performance estimation model generated by the service specifying device based on the network configuration graph in the second embodiment;

FIG. 24 is a schematic diagram of a local configuration graph used to generate a container performance estimation model according to the second embodiment;

FIG. 25 is a schematic diagram of the container performance estimation model generated by the service specifying device based on the local configuration graph in the second embodiment;

FIG. 26 is a schematic diagram of an estimation model that estimates the performance of the service according to the second embodiment;

FIG. 27 is a schematic diagram illustrating a method of estimating a response time of the service when the container is scaled out in the second embodiment;

FIG. 28 is a schematic diagram in the case where a scale-out destination and a scale-out source are geographically separated from each other in the second embodiment;

FIG. 29 is a block diagram illustrating functional configuration of the service specifying device according to the second embodiment;

FIG. 30 is a flowchart of the service specifying method according to the second embodiment; and

FIG. 31 is a block diagram illustrating hardware configuration of a physical server according to the first and second embodiments.

### DESCRIPTION OF EMBODIMENTS

It is an object of the present disclosure to specify a service whose performance is deteriorated due to the failure of the infrastructure.

Prior to the description of the present embodiment, matters studied by an inventor will be described.

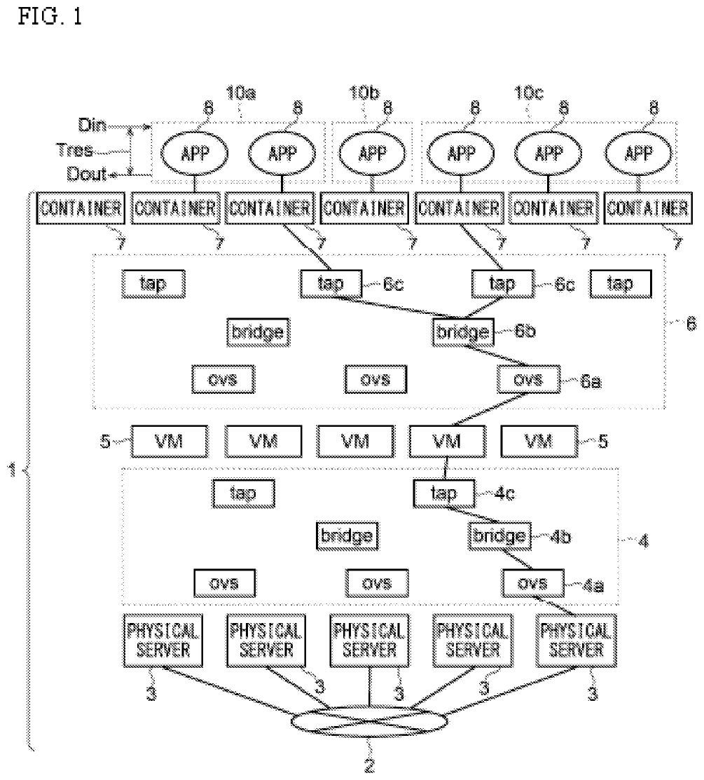

FIG. 1 is a block diagram of infrastructure for realizing a microservice architecture.

In the example of FIG. 1, an infrastructure 1 includes a physical network 2, a plurality of physical servers 3, a first virtual network 4, a plurality of virtual machines 5, a second virtual network 6, and a plurality of containers 7.

The physical network 2 is a network such as a LAN (Local Area Network) or the Internet that connects the plurality of physical servers 3 to each other.

Further, each physical server 3 is a computer such as a server or a PC (Personal Computer) that executes the plurality of virtual machines 5.

The first virtual network 4 is a virtual network generated by each of the plurality of physical servers 3, and connects the plurality of virtual machines 5 to each other. As an example, the first virtual network 4 includes first virtual switches 4a, first virtual bridges 4b, and first virtual taps 4c. The first virtual tap 4c is an interface between the first virtual network 4 and the virtual machine 5.

The virtual machine 5 is a virtual computer realized by a VM (Virtual Machine) virtualization technology that executes a guest OS on a host OS (Operating System) of the physical server 3.

The second virtual network 6 is a virtual network generated by each of the plurality of virtual machines 5, and connects the plurality of containers 7 to each other. In this example, the second virtual network 6 includes second virtual switches 6a, second virtual bridges Gb, and second virtual taps Ge. The second virtual tap Gc is an interface between the second virtual network 6 and the container 7.

The container 7 is a virtual user space realized on the virtual machine 5 by the container virtualization technology. Since the container virtualization technology virtualizes only a part of the kernel of the guest OS, it has an advantage that the virtualization overhead is small and light weight. Then, an application 8 is executed in each of the containers 7. The application 8 is an application program executed by each container 7.

In the microservice architecture, one application 8 is also called a microservice. Then, a plurality of services 10a to 10c are constructed by the plurality of applications 8.

Each of the services 10a to 10c is a service that the user uses via a user terminal such as a PC. As an example, when the user terminal inputs some input data Din to the service 10a, the service 10a outputs output data Dout obtained by performing a predetermined process on the input data.

A response time Tres is an index for measuring the performance of the service 10a. In this example, the time from when the service 10a receives the input of the input data Din to when it outputs the output data Dout is defined as the response time. The response times for the services 10b and 10c are the same as the response time for the service 10a. The smaller the response time, the faster the user can acquire the output data Dout, which can contribute to the convenience of the user.

However, if a failure occurs in a part of the infrastructure 1, the response time of any of the services 10a to 10c may increase as described below.

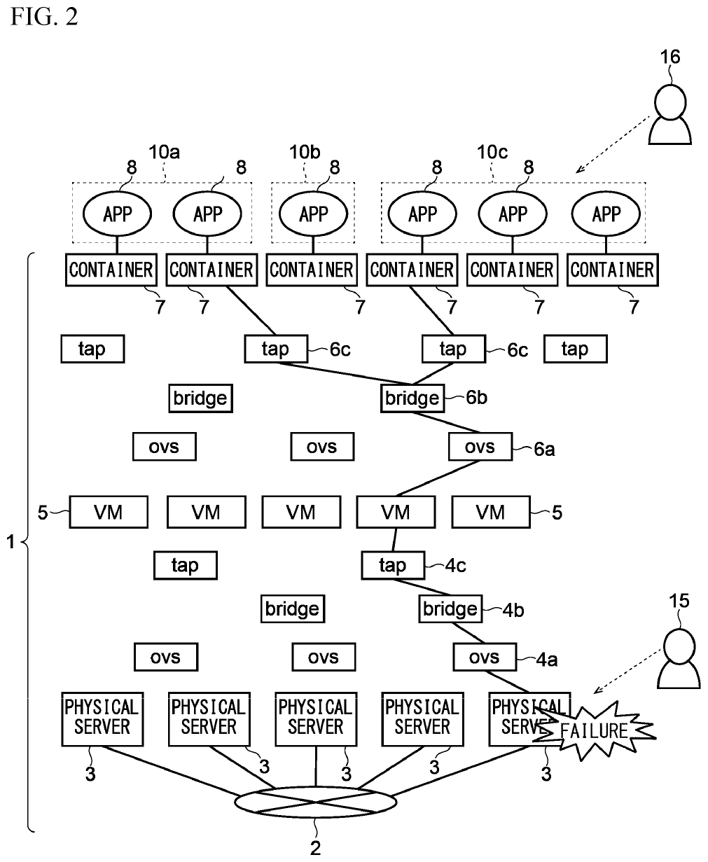

FIG. 2 is a schematic diagram of the infrastructure 1 when the failure occurs.

An example in FIG. 2 illustrates a case in which the failure occurs in one of the plurality of physical servers 3.

Since an operator 15 of the infrastructure 1 constantly monitors whether the failure occurs in the infrastructure 1, it is possible to specify a machine in which the failure occurs among the plurality of physical servers 3.

However, an administrator of the application 8 included in each of the services 10a to 10c is often an operator 16 of each of the services 10a to 10c, not the operator 15 of the infrastructure 1.

Therefore, the operator 15 of the infrastructure 1 cannot specify a service affected by the physical server 3 in which the failure occurs among the services 10a to 10c. As a result, it is not possible to take measures such as scaling out the container 7 affected by the physical server 3 in which the failure occurs to a physical server 3 in which the failure does not occur, which reduces the convenience of a user.

In order to specify the service affected by the failure, a configuration graph may be used as follows.

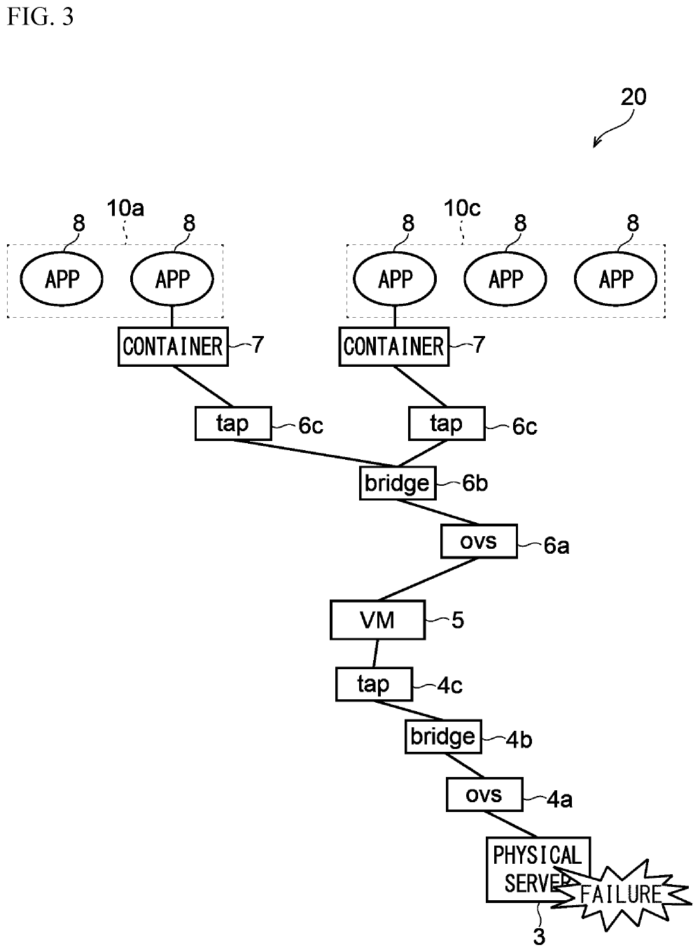

FIG. 3 is a diagram illustrating an example of the configuration graph.

A configuration graph 20 is a graph indicating a dependency relationship between the components of the infrastructure 1. By using the configuration graph 20, it is possible to specify the container 7 that depends on the physical server 3 in which the failure occurs. Therefore, the application 8 executed by the container 7 can be specified, and the services 10a and 10c affected by the physical server 3 in which the failure occurs can be specified among the services 10a to 10c.

However, in an actual system, a large number of services may share the components of the infrastructure 1, so this method may specify an extremely large number of services.

Moreover, an amount of increase in the response time Tres due to the failure of the physical server 3 is expected to be different for each of the services 10a to 10c. In spite of this, this method cannot specify a service whose response time Tres increased significantly due to the failure that occurred in the physical server 3.

As a result, it is not possible to specify the container 7 that executes the service that require an immediate response due to a large increase in the response time Tres, and it is not possible to take measures such as promptly scaling out the container 7 to the normal physical server 3.

Alternatively, a method of estimating the response time of the services 10a to 10c is also considered by using an estimation model as follows.

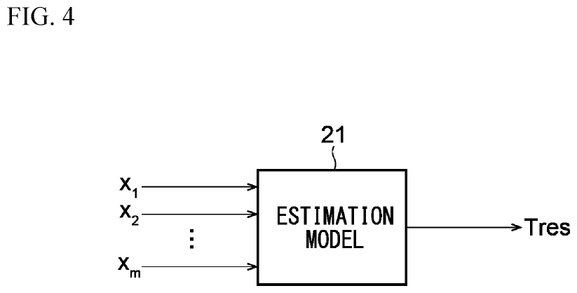

FIG. 4 is a schematic diagram for explaining the estimation model.

An estimation model 21 is a model that estimates the performance of the service 10a based on the loads of all the resources included in the infrastructure 1. The resources to be input are all the resources included in the physical network 2, all the physical servers 3, the first virtual network 4, all the virtual machines 5, the second virtual network 6, and all the containers 7.

The estimation model 21 is a model that calculates the response time of the service 10a, for example, based on the following equation (1).

Response time of service 10a=a₁×x₁+a₂×x₂+ . . . +aₘ×xₘ (1)

Wherein x₁, x₂, . . . , and xₘ are parameters that indicate the loads of all the resources included in the infrastructure 1. Such parameters include, for example, the CPU usage rate of each of the physical servers 3, the virtual machines 5 and the containers 7. Further, there is a traffic as a parameter indicating the load of each of the first virtual network 4 and the second virtual network 6. The traffic is an amount of data that passes through the first virtual switch 3a and the second virtual switch 6a per unit time.

Further, a₁, a₂, . . . , and aₘ are coefficients obtained by multiple regression analysis based on the past parameters x₁, x₂, . . . , and xₘ and the actual measured values of the past response time Tres of the service 10a. Then, m is the number of all resources included in the infrastructure 1.

By generating such an estimation model 21 for each of the services 10a to 10c, the response time Tres can be obtained for each of the services 10a to 10c.

However, since the load of the resource not used by the service 10a is also input to the estimation model 21 of the service 10a, an estimation accuracy of the response time Tres of the service 10a deteriorates by the load of the resource.

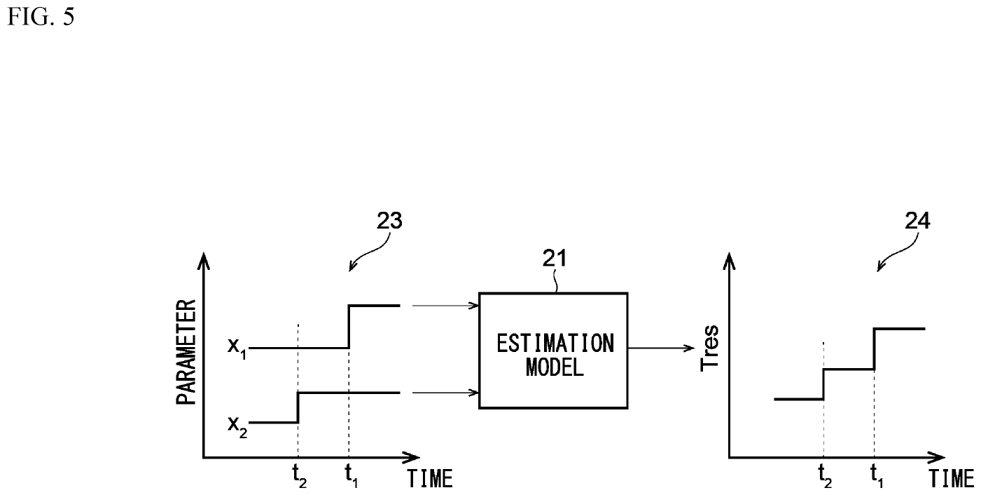

FIG. 5 is a schematic diagram illustrating that the estimation accuracy deteriorates.

In FIG. 5, for the sake of simplicity, it is assumed that the service 10a uses only a resource R₁ and the service 10b uses only a resource R₂ among all the resources included in the infrastructure 1. Then, a parameter indicating the load of the resource R₁ is x₁, and a parameter indicating the load of the resource R₂ is x₂. As an example, the resource R₁ is the CPU usage rate of the virtual machine 5 that is used by the service 10a and not used by the service 10b. Also, the resource R₂ is the CPU usage rate of the virtual machine 5 that is used by the service 10b and not used by the service 10a.

It is assumed that the time change of each of parameters x₁ and x₂ changes as illustrated in a graph 23, for example. Here, it is assumed that the parameter x₁ greatly increases at the time t₁ and the parameter x₂ greatly increases at the time t₂, as illustrated in the graph 23.

The estimation model 21 estimates the response time Tres of the service 10a based on the parameters x₁ and x₂.

A graph 24 is a graph illustrating the time change of the response time Tres estimated in this way.

As described above, the service 10a uses only the resource R₁ and does not use the resource R₂. Therefore, the time change of the response time Tres of the service 10a should change significantly only at the time t₁ according to the parameter x₁ indicating the load of the resource R₁.

However, in the example of the graph 24, it is estimated that the response time Tres of the service 10a increases not only at the time t₁ but also at the time t₂ when the load of the resource R₂ increases. Thus, this method makes it difficult to accurately estimate the response time of the service 10a because the load of the resource R₂ becomes noise.

Hereinafter, each embodiment will be described.

### First Embodiment

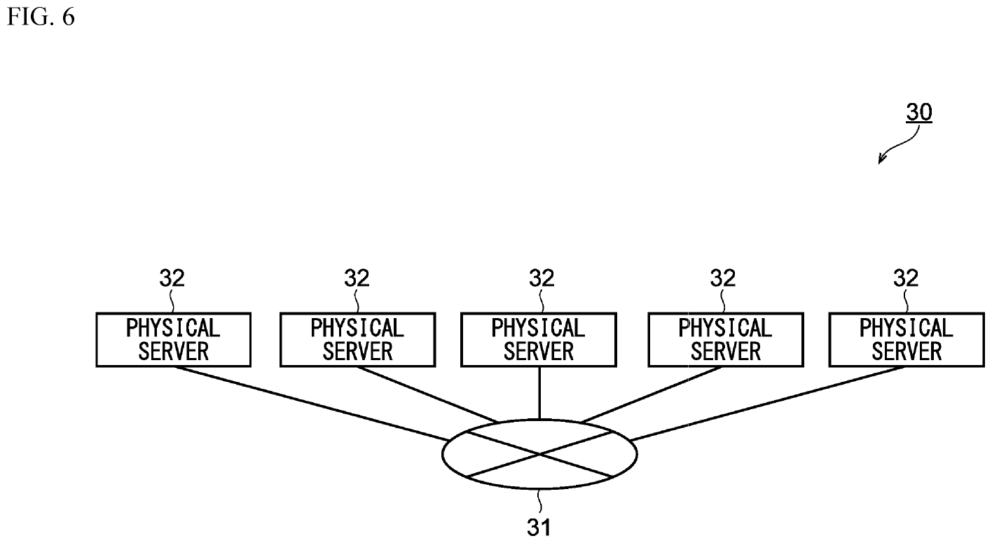

FIG. 6 is a block diagram of a system according to a first embodiment.

A system 30 is a system adopting the microservice architecture, and has a plurality of physical servers 32 connected to each other via a physical network 31.

As an example, the physical network 31 is a LAN (Local Area Network) or an Internet. Further, the physical server 32 is a computer such as a PC (Personal Computer) or a server.

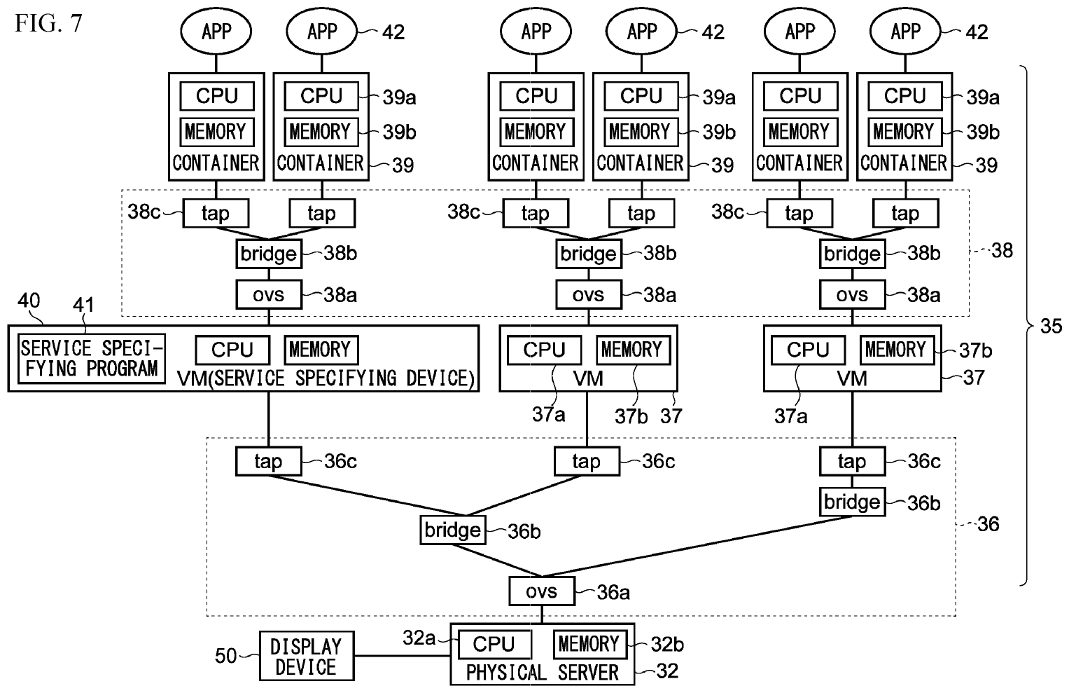

FIG. 7 is a schematic diagram of a virtualized environment realized by the physical server 32.

As illustrated in FIG. 7, the physical server 32 includes a CPU 32a and a memory 32b. The CPU 32a and the memory 32b work together and execute a virtualization program to realize a virtualized environment 35.

In this example, the virtualized environment 35 includes a first virtual network 36, a plurality of virtual machines 37, a second virtual network 38, and a plurality of containers 39.

The first virtual network 36 is a virtual network generated by each of the plurality of physical servers 32, and connects the plurality of virtual machines 37 to each other. As an example, the first virtual network 36 includes a first virtual switch 36a, first virtual bridges 36b, and first virtual taps 36c. The first virtual tap 36c is an interface between the first virtual network 36 and the virtual machines 37.

The virtual machine 37 is a virtual computer realized by VM virtualization technology that executes a guest OS on a host OS of the physical server 32. The virtual machine 37 has a first virtual CPU 37a and a first virtual memory 37b. The first virtual CPU 37a is a virtual CPU that allocates a part of the CPU 32a of the physical server 32 to the virtual machine 37. Then, the first virtual memory 37b is a virtual memory that allocates a part of the memory 32b of the physical server 32 to the virtual machine 37.

The first virtual CPU 37a and the first virtual memory 37b work together and execute a container engine, which realize the second virtual network 38 and the container 39. The container engine is not particularly limited, but for example, DOCKER (registered trademark) can be used as the container engine.

It should be noted that one of the plurality of virtual machines 37 stores a service specifying program 41 that specifies a service whose performance is significantly deteriorated among the plurality of services provided by the system 30. The first virtual CPU 37a and the first virtual memory 37b work together and execute the service specifying program 41, so that the virtual machine 37 functions as a service specifying device 40. Then, the service specified by the service specifying device 40 is displayed on a display device 50 such as a liquid crystal display connected to the physical server 32.

The second virtual network 38 is a virtual network that connects the plurality of containers 39 to each other. In this example, the second virtual network 38 includes second virtual switches 38a, second virtual bridges 38b and second virtual taps 38c. The second virtual tap 38c is an interface between the second virtual network 38 and the containers 39.

The container 39 is a virtual user space realized on the virtual machine 37 by the container virtualization technology, and has a second virtual CPU 39a and a second virtual memory 39b.

The second virtual CPU 39a is a virtual CPU that allocates a part of the first virtual CPU 37a of the virtual machine 37 to the container 39. The second virtual memory 39b is a virtual memory that allocates a part of the first virtual memory 37b of the virtual machine 37 to the container 39.

Then, the second virtual CPU 39a and the second virtual memory 39b work together to execute the application 42.

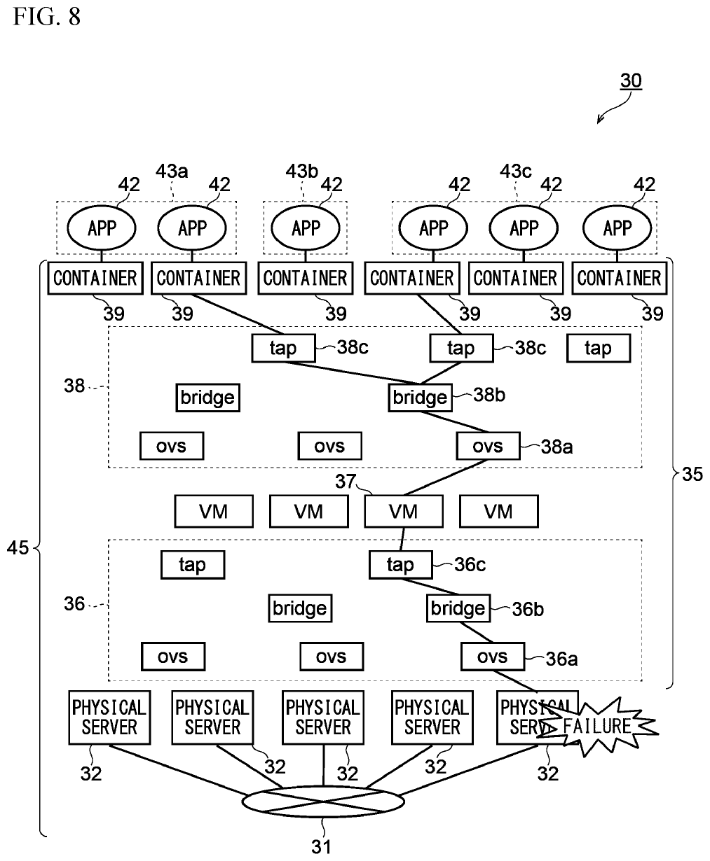

FIG. 8 is a schematic diagram of the service realized by the system 30.

In the present embodiment, a plurality of services 43a to 43c are constructed by the plurality of applications 42, as illustrated in FIG. 8. Hereinafter, the infrastructure that executes these services 43a to 43c is referred to as an infrastructure 45. In this example, the infrastructure 45 includes the physical network 31, the plurality of physical servers 32, and the virtualized environment 35.

When the failure occurs in the infrastructure 45, the performance such as the response time of the plurality of services 43a to 43c deteriorates. Hereinafter, among the elements included in the infrastructure 45, elements that may deteriorate the performance of each of the services 43a to 43c in this way are referred to as resources.

For example, the physical servers 32, the virtual machines 37 and the containers 39 are the resources. Further, the first and the second virtual switches 36a and 38a, the first and the second virtual bridges 36b and 38b, and the first and the second virtual taps 36c and 38c are also examples of the resources.

When the failure occurs in any of these resources, the performance such as response time of each of the services 43a to 43c deteriorates. However, a degree of deterioration in performance differs depending on whether each of the services 43a to 43c are using the resource in which the failure occurs.

Therefore, in the present embodiment, among the plurality of services 43a to 43c, the service whose performance is significantly deteriorated is specified as follows, and the container 39 or the like that executes the service is preferentially scaled out.

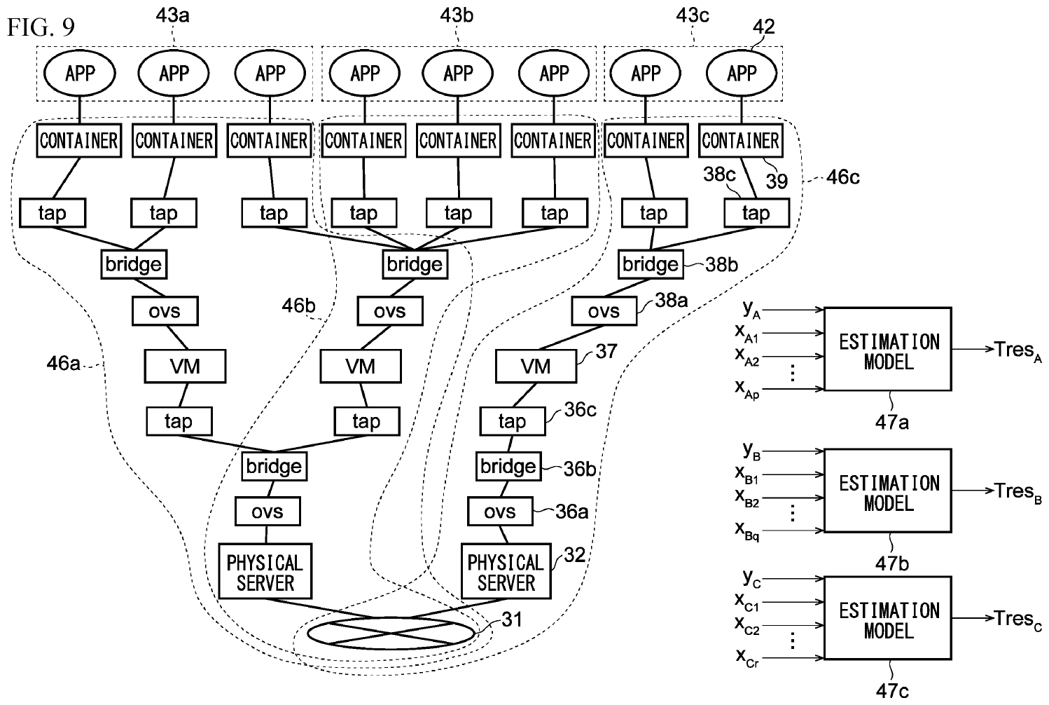

FIG. 9 is a schematic diagram illustrating a service specifying method according to the present embodiment.

In the present embodiment, the service specifying device 40 generates configuration graphs 46a to 46c for the plurality of services 43a to 43c, respectively, as illustrated in FIG. 9.

The configuration graph 46a is a graph in which the components of the resources used by the service 43a are connected to each other. Similarly, the configuration graph 46b is a graph in which the components of the resources used by the service 43b are connected to each other, and the configuration graph 46c is a graph in which the components of the resources used by the service 43c are connected to each other.

Then, the service specifying device 40 acquires parameters x_{A1} to x_{Ap} indicating the loads of the resources included in the configuration graph 46a. Similarly, the service specifying device 40 acquires parameters x_{B1} to x_{Bq} indicating the loads of the resources included in the configuration graph 46b, and parameters xci to x_{Cr} indicating the loads of the resources included in the configuration graph 46c.

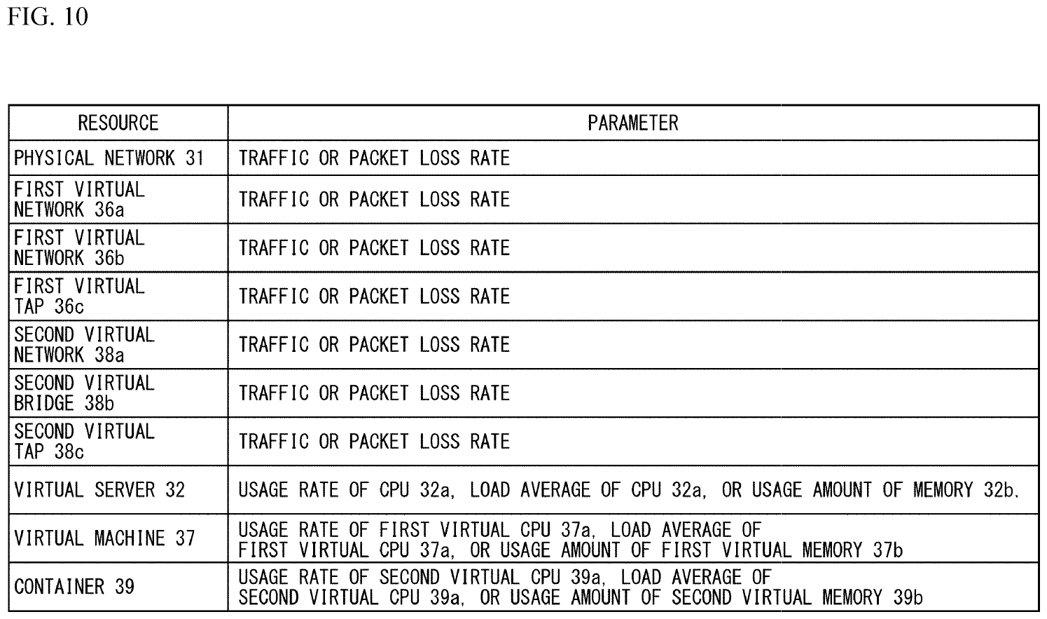

FIG. 10 is a diagram illustrating an example of the parameters x_{A1} to x_{Ap}, x_{B1} to x_{Bq}, and x_{C1} to x_{Cr}.

As illustrated in FIG. 10, each parameter of the physical network 31, the first virtual network 36 and the second virtual network 38 includes a traffic or packet loss rate in each network. The traffic of the first virtual network 36 is an amount of data passing through any of the first virtual switch 36a, the first virtual bridge 36b and the first virtual tap 36c per unit time. Further, the traffic of the second virtual network 38 is an amount of data passing through any of the second virtual switch 38a, the second virtual bridge 38b and the second virtual tap 38c per unit time.

On the other hand, the parameter of the physical server 32 includes a usage rate of the CPU 32a, a load average of the CPU 32a, or a usage rate of the memory 32b. The parameter of the virtual machine 37 includes a usage rate of the first virtual CPU 37a, a load average of the first virtual CPU 37a, or a usage rate of the first virtual memory 37b. The parameter of the container 39 includes a usage rate of the second virtual CPU 39a, a load average of the second virtual CPU 39a, or a usage rate of the second virtual memory 39b.

FIG. 9 is referred to again.

Next, the service specifying device 40 generates an estimation model 47a that estimates the performance of the service 43a. The input data of the estimation model 47a includes the parameters x_{A1} to x_{Ap}, and the number of accesses y_{A} to the service 43a. The number of accesses y_{A} is the number of accesses from the user terminal to the service 43a per unit time. The performance of the service 43a estimated by the estimation model 47a is, for example, the response time Tres_{A} of the service 43a.

For example, the service specifying device 40 generates the estimation model 47a by using the actual measured values of the past parameters x_{A1} to x_{Ap}, the actual measured value of the past number of accesses y_{A}, and the actual measured value of the past response time Tres_{A} of the service 43a as learning data.

Similarly, the service specifying device 40 also generates an estimation model 47b and an estimation model 47c. The estimation model 47b is a model that estimates the response time Tres_{B} of the service 43b based on the parameters x_{B1} to x_{Bq} and the number of accesses yₙ to the service 43b per unit time. Then, the estimation model 47c is a model that estimates the response time Tres_{C} of the service 43c based on the parameters x_{C1} to x_{Cr}, and the number of accesses y_{C} to the service 43c per unit time.

Further, the service specifying device 40 monitors whether the failure does not occur in the resource based on a current value of each of the parameters x_{A1} to x_{Ap}, x_{B1} to x_{Bq}, and x_{C1} to x_{Cr}.

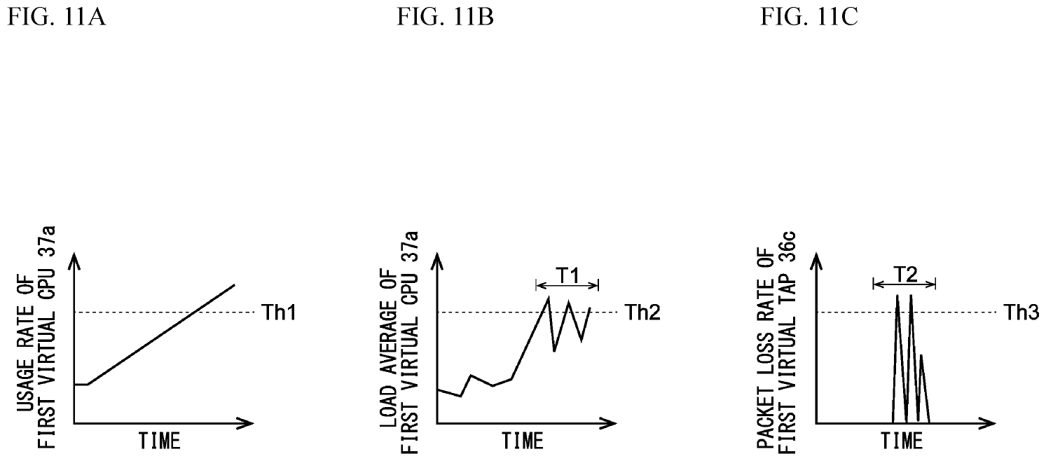

FIGS. 11A to 11C are schematic diagrams illustrating a method in which the service specifying device 40 determines whether the failure occurs in the resource.

FIG. 11A is a schematic diagram illustrating a method of determining whether the failure occurs in the virtual machine 37. A horizontal axis of FIG. 11A indicates time, and a vertical axis indicates a usage rate of the first virtual CPU 37a of the virtual machine 37.

In this example, a threshold value Th1 is set in advance to the usage rate of the first virtual CPU 37a, and the service specifying device 40 determines that an abnormality occurs in the virtual machine 37 when the usage rate exceeds the threshold value Th1. The threshold value Th1 is not particularly limited, but for example, the threshold value Th1 is 90%.

FIG. 11B is a schematic diagram illustrating another method of determining whether the failure occurs in the virtual machine 37. A horizontal axis of FIG. 11B indicates time, and a vertical axis indicates a load average of the first virtual CPU 37a of the virtual machine 37.

In this example, a threshold value Th2 is set in advance to the load average of the first virtual CPU 37a. When the number of times the load average exceeds the threshold value Th2 during a predetermined time T1 becomes the predetermined number of times M1 or more, the service specifying device 40 determines that the failure occurs in the virtual machine 37. The predetermined time T1 is 1 minute, and the predetermined number of times M1 is 3 times, for example. The threshold Th2 is 5, for example.

By adopting the CPU 32a or the second virtual CPU 39a instead of the first virtual CPU 37a, the service specifying device 40 can determine whether the physical server 32 or the container 39 fails in the same manner as in FIGS. 11A and 11B.

FIG. 11C is a schematic diagram illustrating a method of determining whether the failure occurs in the first virtual network 36. A horizontal axis of FIG. 11C indicates time, and a vertical axis indicates a packet loss rate of the first virtual tap 36c.

In this example, a threshold value Th3 is set in advance to the packet loss rate in the first virtual tap 36c. When the number of times the packet loss rate exceeds the threshold value Th3 during a predetermined time T2 becomes the predetermined number of times M2 or more, the service specifying device 40 determines that the failure occurs in the first virtual network 36. The predetermined time T2 is 1 minute, and the predetermined number of times M2 is 2 times, for example. The threshold Th3 is 10 times/second, for example.

As described above, the first virtual network 36 is described as an example. However, by adopting the packet loss rate of the second virtual tap 38c instead of the first virtual tap 36c, the service specifying device 40 can determine whether the failure occurs in the second virtual network 38.

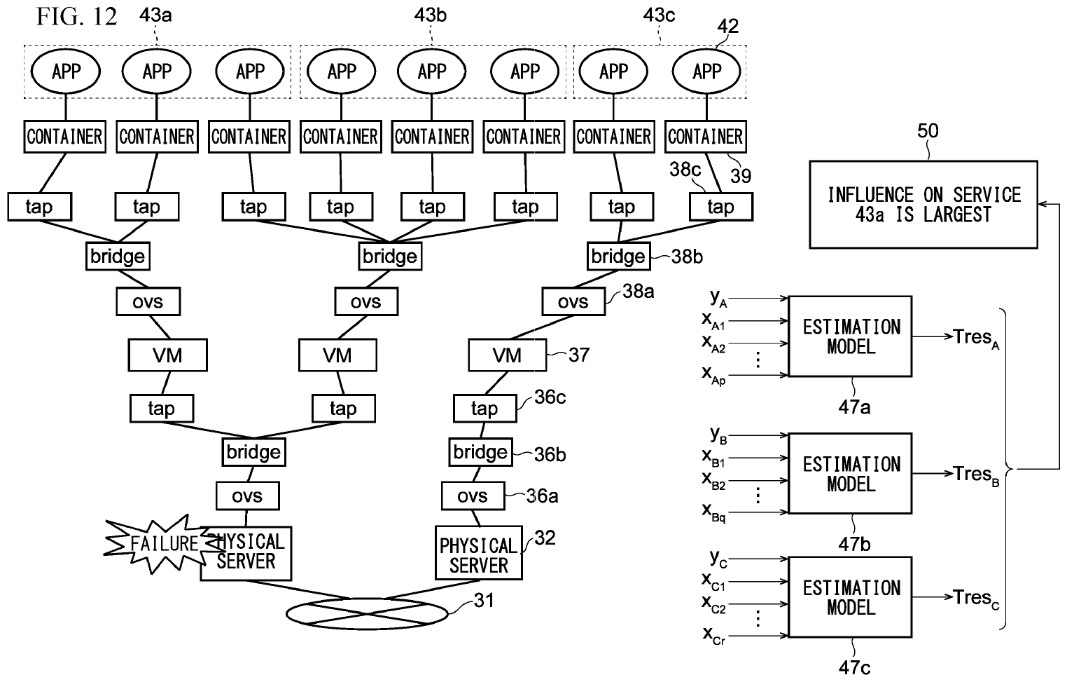

FIG. 12 is a schematic diagram illustrating a process performed by the service specifying device 40 when it is determined that the failure occurs in the resource.

In FIG. 12, it is assumed that the failure occurs in one of the plurality of physical servers 32. In this case, the service specifying device 40 estimates the performances of the services 43a to 43c using the estimation models 47a to 47c, respectively.

For example, the service specifying device 40 estimates the response time Tres_{A} as the performance of the service 43a by inputting a current value of each of the parameters x_{A1} to x_{Ap} and the number of accesses y_{A} into the estimation model 47a.

At this time, in the present embodiment, the parameters x_{A1} to x_{Ap} indicating the load of respective resources used by the service 43a are input to the estimation model 47a, and the parameters x_{B1} to x_{Bq} and x_{C1} to x_{Cr} related to the services 43b and 43c are not input to the estimation model 47a. Therefore, it is possible to suppress the deterioration of the estimation accuracy of the response time Tres_{A} of the service 43a due to the parameters x_{B1} to x_{Bq} and x_{C1} to x_{Cr}, and it is possible to estimate the performance of the service 43a with high accuracy based on the estimation model 47a.

Similarly, the service specifying device 40 estimates the response time Tres_{B} of the service 43b by inputting the parameters x_{B1} to x_{Bq} and the number of accesses y_{B} into the estimation model 47b. Also in this case, since the parameters x_{A1} to x_{Ap} and x_{C1} to x_{Cr} related to the services 43a and 43c are not input to the estimation model 47b, it is possible to suppress the deterioration of the estimation accuracy of the response time Tres_{B} due to the parameters.

Further, the service specifying device 40 estimates the response time Tres_{C} of the service 43c by inputting the parameters x_{C1} to x_{Cr} and the number of accesses y_{C} into the estimation model 47c.

Then, the service specifying device 40 specifics the service whose performance is deteriorated among the plurality of services 43a to 43c. For example, the service specifying device 40 sets a threshold value Tres0 in advance to each of the response times Tres_{A}, Tres_{B}, and Tres_{C}. Then, the service specifying device 40 specifies a service whose response time exceeds the threshold value Tres0 as the service whose performance is deteriorated, among the plurality of services 43a to 43c. In the example of FIG. 12, it is assumed that the response time Tres, of the service 43a exceeds the threshold value Tres0 among the plurality of services 43a to 43c.

In this case, the service affected by the performance deterioration due to a physical server 32 in which the failure occurs is the service 43a, and it is necessary to give priority to measures for the service 43a over the other services 43b and 43c. Therefore, the service specifying device 40 outputs an instruction for displaying the specified service 43a to the display device 50.

As an example, the service specifying device 40 outputs, to the display device 50, an instruction to display a message “The influence on service 43a is the largest”.

Instead of this, the display device 50 may provide a graphical display as follows.

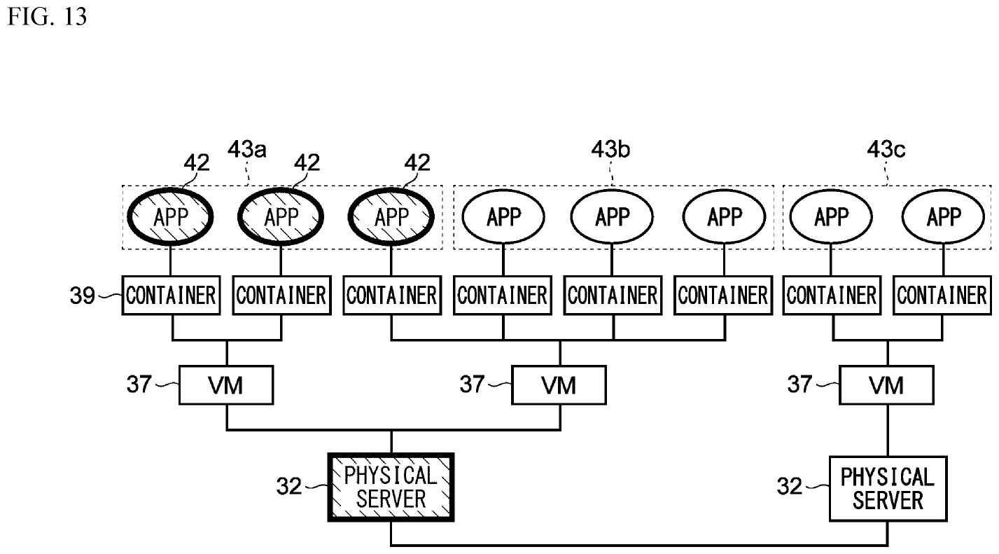

FIG. 13 is a schematic diagram illustrating another display example of the display device 50.

In this example, the display device 50 graphically displays a connection relationship between the physical servers 32, the virtual machines 37, the containers 39, and the applications 42 in the system 30, as illustrated in FIG. 13. Then, the display device 50 highlights the application 42 that executes the service 43a whose performance is deteriorated among the plurality of services 43a to 43c, and the physical server 32 in which the failure occurs.

Thereby, the administrator of the infrastructure 45 can specify the container 39 executing the service 43a that requires immediate measures, and promptly can take measures such as scaling out the container 39 to the physical server 32 in which the failure does not occur.

According to the service specifying method described above, the service specifying device 40 estimates the performances of the services 43a to 43c based on the estimation models 47a to 47c, respectively, as illustrated in FIG. 12.

The estimation model 47a uses the parameters x_{A1} to x_{Ap} indicating the load of the resources used by the service 43a to be estimated and the number of accesses y_{A} as input data, and does not use the parameters and the number of accesses related to the services 43b and 43c as input data. Therefore, it is possible to suppress the estimation accuracy of the performance of the service 43a from deteriorating due to the parameters and the number of accesses related to the service other than the service 43a.

For the same reason, each of the estimation models 47b and 47c can also estimate the performance of each of the services 43b and 43c with high accuracy.

Next, the functional configuration of the service specifying device according to the present embodiment will be described.

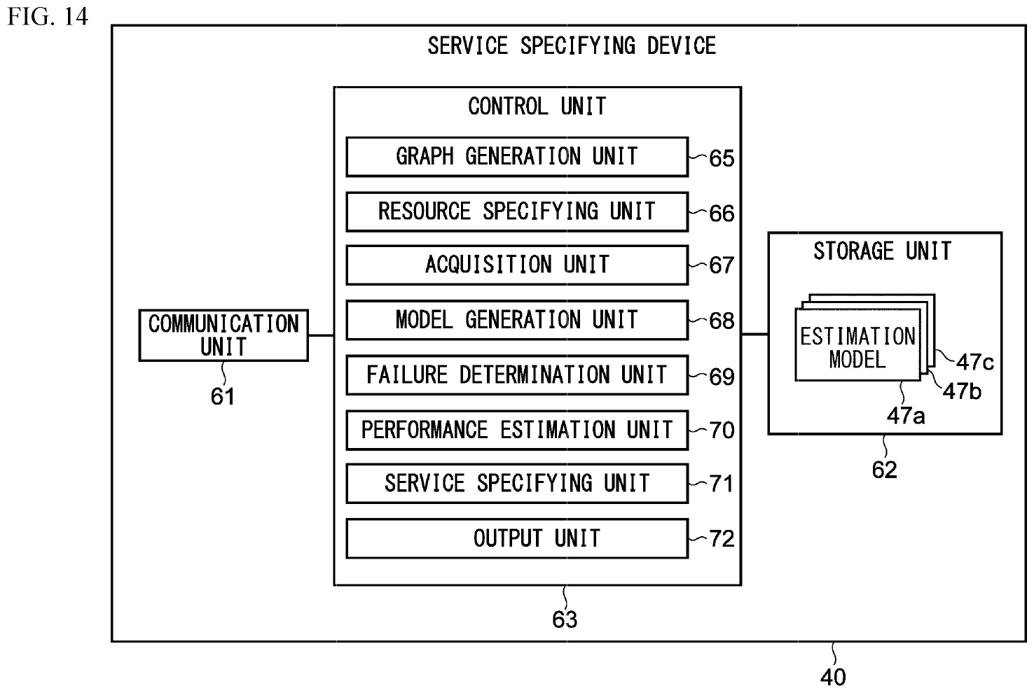

FIG. 14 is a block diagram illustrating functional configuration of the service specifying device according to the present embodiment.

The service specifying device 40 includes a communication unit 61, a storage unit 62, and a control unit 63, as illustrated in FIG. 14.

The communication unit 61 is an interface for connecting the service specifying device 40 to the first virtual network 36. Further, the storage unit 62 stores the estimation models 47a to 47c for the plurality of services 43a to 43c, respectively.

Then, the control unit 63 is a processing unit that controls each unit of the service specifying device 40. As an example, the control unit 63 includes a graph generation unit 65, a resource specifying unit 66, an acquisition unit 67, a model generation unit 68, a failure determination unit 69, a performance estimation unit 70, a service specifying unit 71, and an output unit 72.

The graph generation unit 65 is a processing unit that generates the configuration graphs 46a to 46c illustrated in FIG. 9 for the service 43a to 43e, respectively. In generating the configuration graphs 46a to 46c, the graph generation unit 65 acquires the information required to generate the configuration graphs 46a to 46c from various softwares.

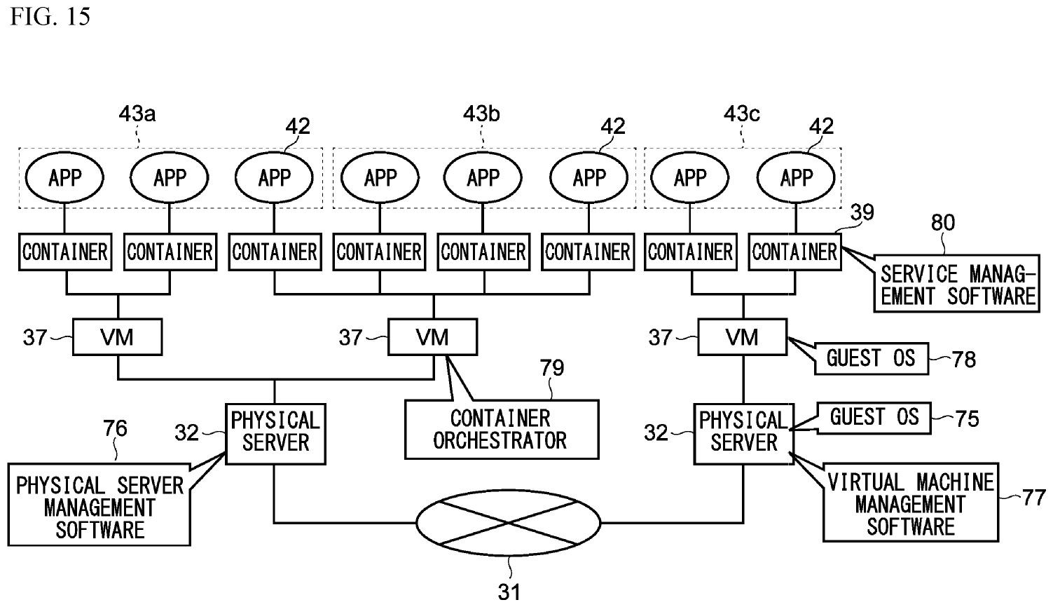

FIG. 15 is a schematic diagram illustrating deployment destinations of these softwares.

As illustrated in FIG. 15, the graph generation unit 65 acquires various information from a host OS 75, a physical server management software 76, a virtual machine management software 77, a guest OS 78, a container orchestrator 79, and a service management software 80.

The host OS 75 is an operating system installed in each of the plurality of physical servers 32. Further, the physical server management software 76 is a software installed in one of the plurality of physical servers 32, and has a function of managing a correspondence relationship between the physical server 32 of a connection destination and the physical server 32 of a connection source that are connected via the physical network 31.

The virtual machine management software 77 is a software installed in one of the plurality of physical servers 32. In this example, the virtual machine management software 77 has a function of managing a correspondence relationship between the virtual machine 37 of the connection destination and the virtual machine 37 of the connection source that are connected via the first virtual network 36.

The guest OS 78 is an operating system installed in each of the plurality of virtual machines 37.

The container orchestrator 79 is a software installed in any one of the plurality of virtual machines 37. For example, the container orchestrator 79 has a function of managing a correspondence relationship between the virtual machine 37 and the container 39 executed by the virtual machine 37.

The service management software 80 is a software installed in any one of the plurality of containers 39. The service management software 80 has a function of managing correspondence relationships between the plurality of services 43a to 43c and the plurality of applications 42.

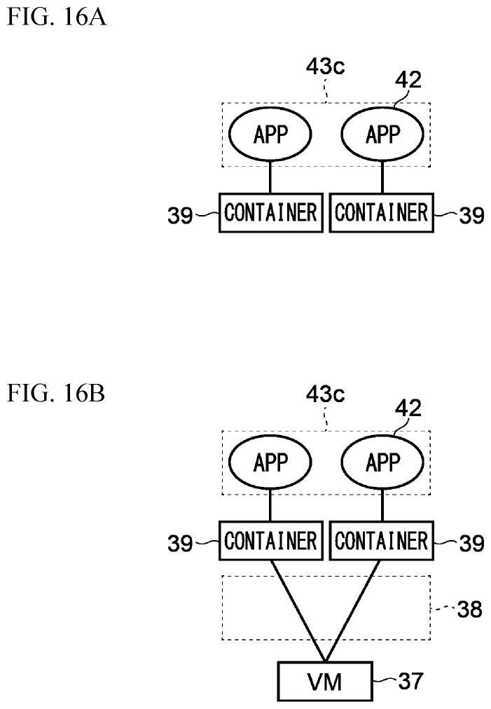

FIGS. 16A to 18B are schematic diagrams of a generating method of the configuration graph 46c.

First, as illustrated in FIG. 16A, the graph generation unit 65 uses the function of the service management software 80 to specify the containers 39 for executing the applications 42 for the service 43c.

Next, as illustrated in FIG. 16B, the graph generation unit 65 uses the function of the container orchestrator 79 to generate a subgraph indicating a connection relationship between the containers 39 and the virtual machine 37.

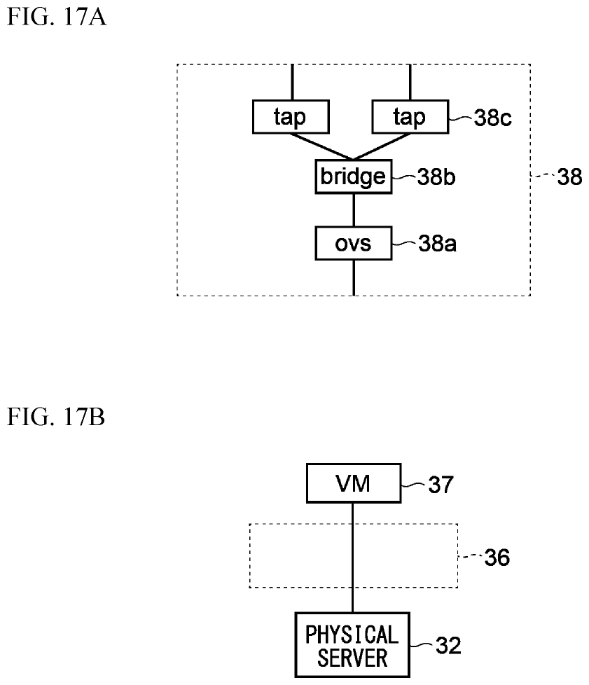

Next, as illustrated in FIG. 17A, the graph generation unit 65 uses the function of the guest OS 78 of the virtual machine 37 to generate a subgraph between the resources of the second virtual network 38. For example, the graph generation unit 65 acquires a process ID of the container 39 from the guest OS 78. Then, the graph generation unit 65 specifies the resources used for communication by the container 39 by using the process ID, and generates a subgraph between the resources.

Next, as illustrated in FIG. 17B, the graph generation unit 65 uses the function of the virtual machine management software 77 to generate a subgraph of the first virtual network 36 that connects the virtual machines 37 to each other.

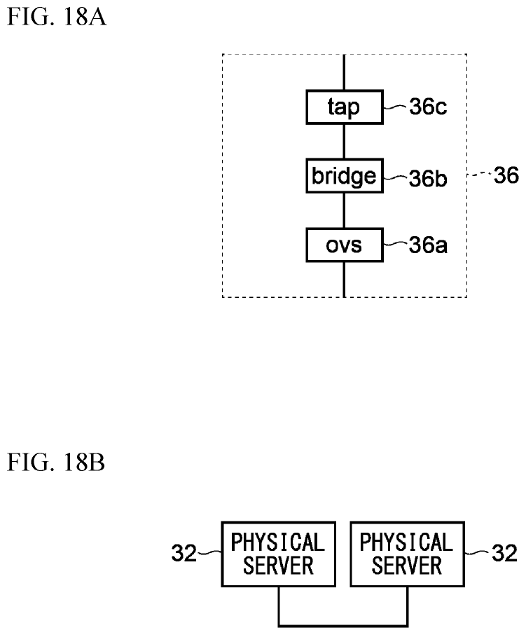

Next, as illustrated in FIG. 18A, the graph generation unit 65 uses the function of the host OS 75 of the physical server 32 to generate a subgraph between the resources of the first virtual network 36. As an example, the graph generation unit 65 acquires the network configuration used by each virtual machine 37 by logging in to the host OS 75, and generate a subgraph based on the network configuration.

Subsequently, as illustrated in FIG. 18B, the graph generation unit 65 uses the function of the physical server management software 76 to generate a subgraph indicating a connection relationship between the plurality of physical servers 32.

Then, the graph generation unit 65 generates the configuration graph 46c by synthesizing the subgraphs generated in FIGS. 16B to 18C. The graph generation unit 65 also generates the configuration graphs 46a and 46b in the same manner as the configuration graph 46c.

FIG. 14 is referred to again.

The resource specifying unit 66 specifies the resources used by the services 43a to 43c based on the configuration graphs 46a to 46c, respectively. For example, the resource specifying unit 66 identifies the node of the configuration graph 46a as the resource used by the service 43a.

The acquisition unit 67 is a processing unit that acquires the parameters x_{A1} to x_{Ap}, x_{B1} to x_{Bq}, and x_{C1} to x_{Cr} indicating the loads of the resources specified by the resource specifying unit 66, for the services 43a to 43c, respectively. Further, the acquisition unit 67 also acquires the number of accesses y_{A}, y_{B}, and y_{C} to the services 43a to 43c.

The model generation unit 68 is a processing unit that generates the estimation models 47a to 47c, for the services 43a to 43c, respectively. For example, the model generation unit 68 generates the estimation model 47a by using the actual measured values of the past parameters x_{A1} to x_{Ap}, the actual measured values of the past number of accesses y_{A}, and the actual measured values of the past response time Tress of the service 43a as learning data.

For example, the model generation unit 68 generates the estimation model 47a by using algorithms such as a multiple regression model, a support vector regression, a decision tree regression method, a neural network, and a recurrent neural network. Further, for the parameters x_{A1} to x_{Ap}, the number of accesses y_{A} and the response time Tres_{A} that are used for learning, a plurality of values in the past fixed period of about 7 days may be used. The model generation unit 68 also generates the estimation models 47b and 47c in the same manner as the estimation models 47a.

The failure determination unit 69 determines whether the failures occur in the resources used by the services 43a to 43c based on the parameters x_{A1} to x_{Ap}, x_{B1} to x_{Bq}, and x_{C1} to x_{Cr}, respectively. For example, the failure determination unit 69 determines that the failure occurs in the virtual machine 37 when the usage rate of the first virtual CPU 37a exceeds the threshold Th1, as illustrated in FIG. 11A. The failure determination unit 69 may determine that the failure occurs by the method described with reference to FIGS. 11B and 11C.

Further, the failure determination unit 69 may determine whether the failure occurs in the resource by using a time series prediction model. Such a time series prediction model includes a local linear regression model, a multiple regression model, an ARIMA (autoregressive integrated moving average model), a recurrent neural network, or the like.

The performance estimation unit 70 is a processing unit that estimates the performance for each of the plurality of services 43a to 43c by using each of the estimation models 47a to 47c when the failure occurs in the resource. For example, the performance estimation unit 70 inputs, to the estimation model 47a, the current parameters x_{A1} to x_{Ap} and the current number of accesses y_{A} to the service 43a per unit time. Then, the performance estimation unit 70 estimates the response time Tres_{A} of the service 43a output by the estimation model 47a as the performance of the service 43a. Similarly, the performance estimation unit 70 estimates each of the response times Tres_{B} and Tres_{C} of the services 43b and 43c, as the performance.

The service specifying unit 71 is a processing unit that specifies, among the plurality of services 43a to 43c, a service whose performance is deteriorated due to the failure of the resource, based on the estimated response times Tres_{A}, Tres_{B}, and Tres_{C}. As an example, the service specifying unit 71 specifies a service whose response time exceeds the threshold value Tres0 as a service whose performance is deteriorated due to the failure of the resource. For example, when the response time Tres_{A} of the service 43a among the services 43a to 43c exceeds the threshold value Tres0, the service specifying unit 71 specifies the service 43a. Alternatively, the service specifying unit 71 may specify the service having the largest response time estimated by the performance estimation unit 70 among the plurality of services 43a to 43c as the service whose performance is deteriorated.

The output unit 72 is a processing unit that outputs, to the display device 50, an instruction for displaying the service specified by the service specifying unit 71 on the display device 50. Upon receiving the instruction, the display device 50 highlights the application 42 that executes the service 43a whose performance is deteriorated among the plurality of services 43a to 43c, and the physical server 32 in which the failure occurs, as illustrated in FIG. 13.

Next, the service specifying method according to the present embodiment will be described.

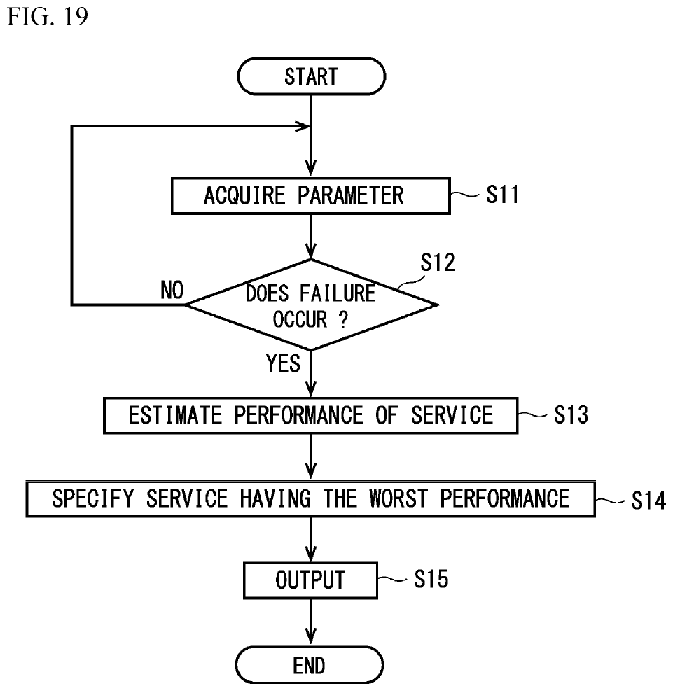

FIG. 19 is a flowchart of the service specifying method according to the present embodiment.

First, the acquisition unit 67 acquires the current values of the parameters x_{A1} to x_{Ap}, x_{B1} to x_{Bq}, and x_{C1} to x_{Cr} indicating the loads of the resources used by the respective services 43a to 43c (step S11). Further, the acquisition unit 67 also acquires the current values of the number of accesses y_{A}, y_{B} and y_{C} to the respective services 43a to 43c.

Next, the failure determination unit 69 determines whether the failures occur in the resources used by the respective services 43a to 43c based on the acquired parameters x_{A1} to x_{Ap}, x_{B1} to x_{Bq}, and xci to x_{Cr} (step S12).

When the failure does not occur (NO in step S12), the process returns to step S11.

On the other hand, when the failure occurs, the process proceeds to step S13.

In step S13, the performance estimation unit 70 estimates the performance for each of the plurality of services 43a to 43c by using the estimation models 47a to 47c. For example, the performance estimation unit 70 estimates the response time Tres_{A} of the service 43a based on the current values of the parameters x_{A1} to x_{Ap} and the number of accesses y_{A}. The performance estimation unit 70 estimates the response times Tres_{B} and Tres_{C} of the services 43b and 43c in the same manner as the response time Tres_{A}.

Next, the service specifying unit 71 specifies the service whose performance estimated in step S13 is deteriorated, among the plurality of services 43a to 43c (step S14).

Subsequently, the output unit 72 outputs, to the display device 50, an instruction for displaying the service specified in step S14 on the display device 50 (step S15).

This completes the basic processing of the service specifying method according to the present embodiment.

According to the present embodiment described above, in step S13, the performance estimation unit 70 estimates the performance for each of the plurality of services 43a to 43c using each of the estimation models 47a to 47c. The estimation model 47a uses the parameters x_{A1} to x_{Ap} indicating the load of the resource used by the service 43a to be estimated and the number of accesses y_{A} as input data, and does not use the parameters and the number of accesses related to the services 43b and 43c as input data. Therefore, it is possible to suppress the deterioration of the estimation accuracy of the performance of the service 43a due to the parameters and the number of accesses related to the service other than the service 43a.

For the same reason, the performance estimation unit 70 can estimate the performance of each of the services 43b and 43c with high accuracy by using each of the estimation models 47b and 47c.

As a result, when the failure occurs in the resource, it is possible to specify the service whose performance is deteriorated among the services 43a to 43c, and promptly take measures such as scaling out the container 39 executing the service. Further, when the resource in which the failure occurs is the physical server 32, it is possible to prevent the service having poor performance from being continuously provided by wasting hardware resources such as the CPU 32a and the memory 32b. This also achieves the technical improvement of preventing the waste of the hardware resources.

### Second Embodiment

As described in the first embodiment, in the microservice architecture, each of the services 43a to 43c uses a plurality of applications 42. The container 39 that executes these applications 42 may be scaled out to another container 39 when the services 43a to 43c are executed. This will be described below.

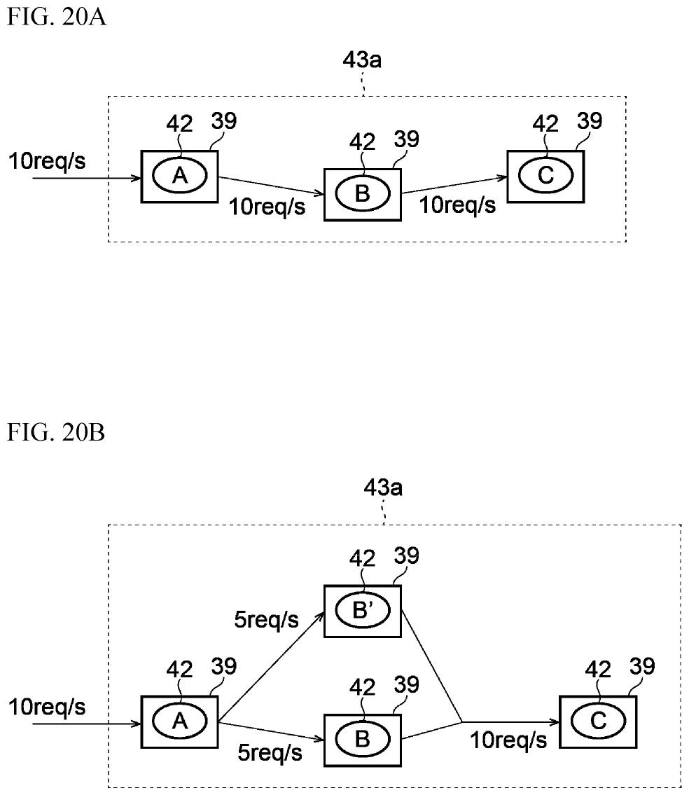

FIG. 20A is a schematic diagram illustrating the service 43a before scale-out, and FIG. 20B is a schematic diagram illustrating the service after scale-out.

As illustrated in FIG. 20A, before the scale-out, each application 42 of three containers 39 cooperates to execute one service 43a. Hereinafter, the plurality of applications 42 are identified by characters “A”, “B” and “C”.

It is assumed that, when the user terminal accesses the “A” application 42 with the number of accesses of 10 req/s, the “A” application 42 accesses the “B” application 42 with the number of accesses of 10 req/s. Similarly, it is assumed that the “B” application 42 accesses the “C” application 42 with the number of accesses of 10 req/s.

At this time, it is assumed that the container 39 executing the “B” application 42 is scaled out as illustrated in FIG. 20B. Here, the application 42 executed by the container 39 of the scale-out source is identified by the character “B” in the same manner as above. Further, the application 42 executed by the container 39 of the scale-out destination is identified by the character “B”. Then, it is assumed that the applications 42 represented by the characters “B” and “B” have the same functions.

When the scale-out is performed in this way, access can be evenly distributed to each of the “B” and “B” applications 42, and the number of accesses to the “B” application 42 of the scale-out source can be reduced to 5 req/s.

Thus, during the operation of the service 43a, the configuration of the infrastructure may be changed due to the scale-out of the container 39. In this case, when the service specifying device 40 newly generates the estimation model 47a of the infrastructure after scale-out, the response time Tres_{A} of the service 43a cannot be estimated until the estimation model 47a is generated. Therefore, in the present embodiment, even if the configuration of the infrastructure is changed due to scale-out, the occurrence of a blank period in which the response time cannot be estimated is suppressed as follows.

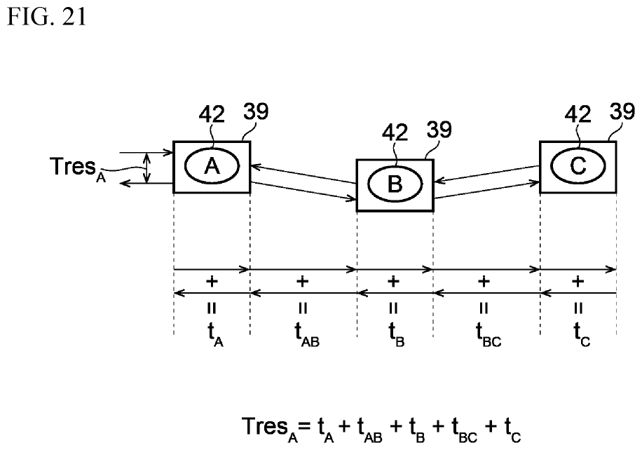

FIG. 21 is a schematic diagram for explaining the service specifying method according to the present embodiment.

As illustrated in FIG. 21, the response time Tres_{A}, which is the performance of the service 43a, is equal to the sum of the processing times t_{A}, t_{B}, and t_{C} of each of the “A”, “B” and “C” applications 42, and the network delay times t_{AB} and t_{BC}.

The processing time t_{A} is the total time required for the processing performed by the “A” application 42 in order to execute the service 43a. Similarly, each of the processing times t_{B} and t_{C} is the total time required for the processing performed by each of the “B” and “C” applications 42 in order to execute the service 43a.

Further, the delay time t_{AB} is the delay time of the network connecting the containers 39 that execute the respective “A” and “B′” applications 42. Similarly, the delay time time is the delay time of the network connecting the containers 39 that execute the respective “B” and “C” applications 42.

In the present embodiment, each of the delay times t_{AB} and t_{BC} is considered as the network performance related to the second virtual network 38 between the containers 39. Further, each of the processing times t_{A}, t_{B}, and t_{C} is considered to be the container performance related to the performance of each container 39.

Then, the service specifying device 40 generates the network performance estimation model that estimates the network performance and the container performance estimation model that estimates the container performance as follows.

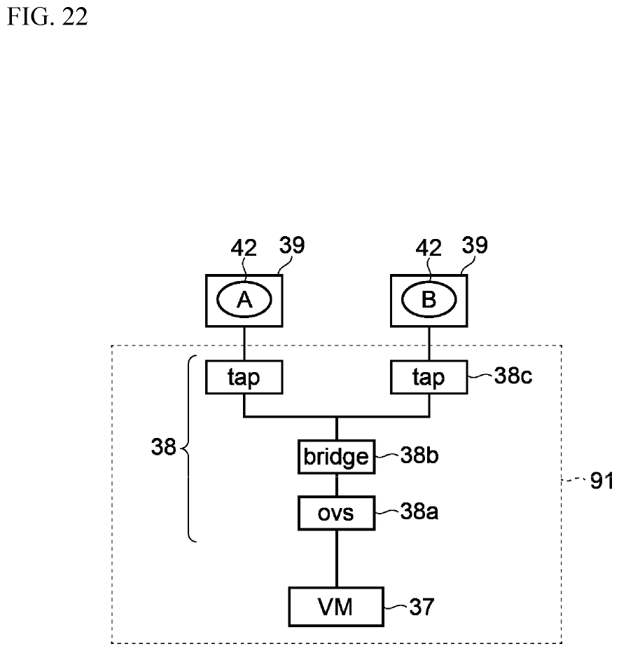

FIG. 22 is a schematic diagram of a network configuration graph used to generate the network performance estimation model.

A network configuration graph 91 is a graph indicating the configuration of the second virtual network 38 between the “A” and “B” applications 42. The nodes of the second virtual network 38 are the second virtual switch 38a, the second virtual bridge 38b, the second virtual taps 38c, and the virtual machine 37.

The service specifying device 40 also generates the network configuration graph 91 for the second virtual network 38 between the “B” and “C” applications 42.

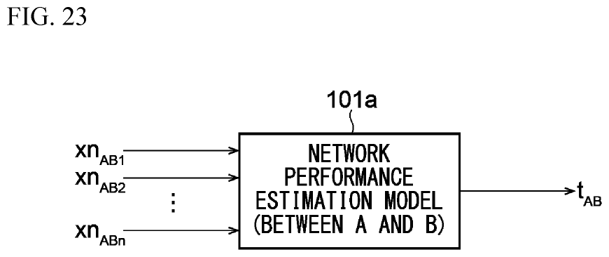

FIG. 23 is a schematic diagram of a network performance estimation model 101a generated by the service specifying device 40 based on the network configuration graph 91 between the “B” and “C” applications 42.

The network performance estimation model 101a is a model that estimates the delay time t_{AB} as the performance of the second virtual network 38 between the “A” and “B” applications 42.

The service specifying device 40 generates the network performance estimation model 101a by using the past measured values of the parameters x_{nAB1} to x_{nABn} indicating the loads of the resources included in the network configuration graph 91 and the past delay time t_{AB} as learning data. The parameters x_{nAB1} to x_{nABn} include, for example, a traffic or packet loss rate flowing through the second virtual network 38. Further, the load of the first virtual CPU 37a of the virtual machine 37 may be adopted as one of the parameters x_{nAB1} to x_{nABn}.

When the current values of the parameters x_{nAB1} to x_{nABn} are input to the network performance estimation model 101a generated in this way, the estimated value of the current delay time t_{AB} is output.

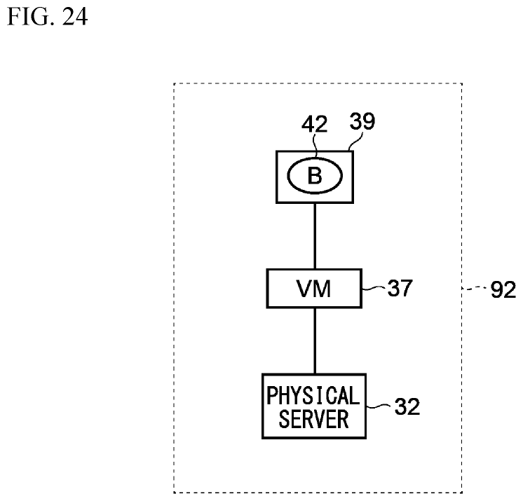

FIG. 24 is a schematic diagram of the local configuration graph used to generate the container performance estimation model.

A local configuration graph 92 is a graph in which the container 39 that executes the “B” application 42 and a resource used by the container 39 are the nodes. In this example, the physical server 32 and the virtual machine 37 executed by the physical server 32 are the nodes of the local configuration graph 92.

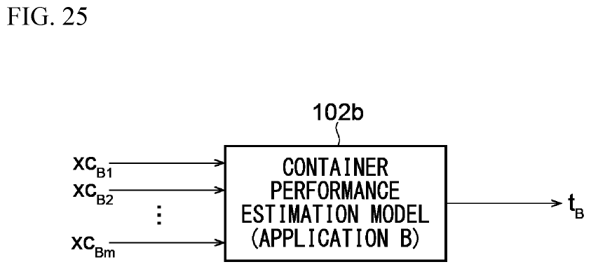

FIG. 25 is a schematic diagram of a container performance estimation model 102b generated by the service specifying device 40 based on the local configuration graph 92.

The container performance estimation model 102b is a model that estimates the processing time t_{B} as the performance of the container 39 that executes the “B” application 42.

The service specifying device 40 generates the container performance estimation model 102b by using the past measured values of the parameters x_{cB1} to x_{cBm} indicating the loads of the resources included in the local configuration graph 92 and the past processing time t_{B} as learning data. The parameters x_{cB1} to x_{cBm} include a load of the second virtual CPU 39a of the container 39, a load of the first virtual CPU 37a of the virtual machine 37, a load of the CPU 32a of the physical server 32, and the like.

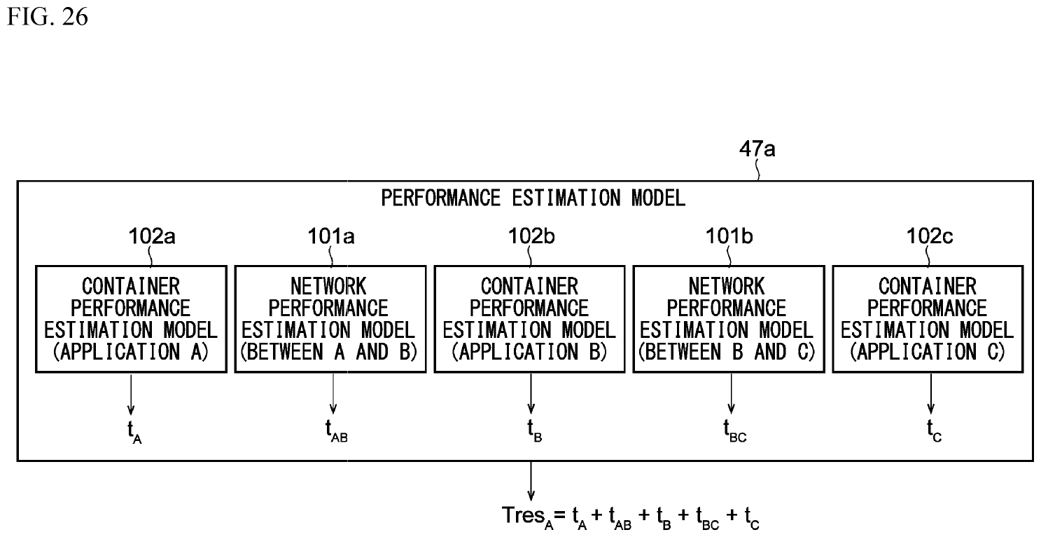

FIG. 26 is a schematic diagram of the estimation model 47a that estimates the performance of the service 43a according to the present embodiment.

As illustrated in FIG. 26, the estimation model 47a has the network performance estimation model 101a relating to the network between “A” and “B”, and a network performance estimation model 101b relating to the network between “B” and “C”. Then, the service specifying device 40 generates the network performance estimation model 101b in the same manner as the network performance estimation model 101a. The network performance estimation models 101a and 101b are examples of the second estimation model.

Further, the estimation model 47a also includes container performance estimation models 102a to 102c of “A”, “B” and “C”. Then, the service specifying device 40 generates the container performance estimation models 102a and 102c in the same manner as the container performance estimation model 102b. The container performance estimation models 102a to 102c are examples of the first estimation model.

The estimation model 47a calculates a total value of the delay times t_{AB} and t_{BC} estimated by the network performance estimation models 101a and 101b and the processing times t_{A}, t_{B} and t_{C} estimated by the container performance estimation models 102a to 102c as the response time Tres_{A}.

Next, it is assumed that the container 39 executing the “B” application 42 is scaled out as illustrated in FIG. 20B. In this case, in the present embodiment, the response time Tres_{A} of the service 43a is estimated as follows.

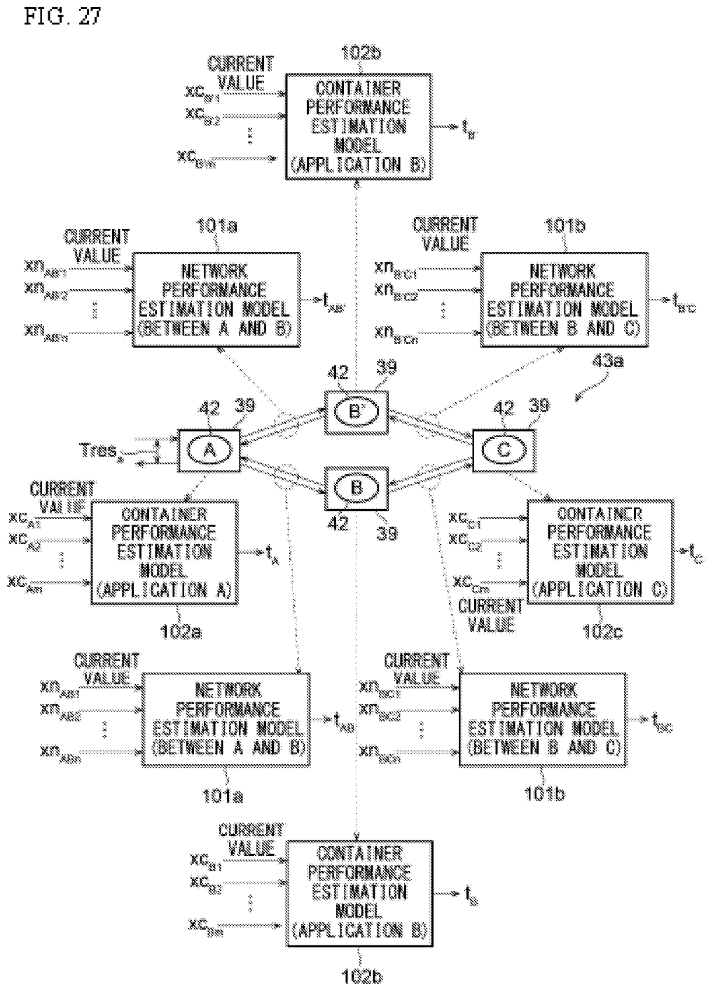

FIG. 27 is a schematic diagram illustrating a method of estimating the response time Tres_{A} of the service 43a when the container 39 executing the “B” application 42 is scaled out.

Here, it is assumed that the “B” application 42 having the same functions as the original “B” application 42 is executed in the container 39 of the scale-out destination, and the service 43a is realized by the “A”, “B”, “B′”, and “C” applications 42.

The container 39 that executes the “A” application 42 is an example of a first container, and the container 39 that executes the “B” application 42 is an example of a second container. Then, the container 39 that executes the “B” application 42 is an example of a third container.

In this case, in the present embodiment, the container performance estimation model 102b of the “B” application 42 of the scale-out source is adopted as the container performance estimation model of the “B′” application 42. The input of the container performance estimation model 102b is the current values of the parameters xc_{B′1} to xc_{B′m} indicating the loads of the same resources as the resources included in the local configuration graph 92 of the container 39 among the plurality of resources executing the “B′” application 42.

Further, the network performance estimation model 101a between “A” and “B” is adopted as the estimation model for estimating the delay time t_{AB′} of the network between “A” and “B′”. The input of the network performance estimation model 101a is the current values of the parameters xn_{AB′1} to xn_{AB′n} indicating the loads of the same resources as the resources included in the network configuration graph 91 between “A” and “B′” among the resources in the second virtual network 38.

Similarly, the network performance estimation model 101b between “B” and “C” is adopted as the estimation model for estimating the delay time t_{B′C} of the network between “B′” and “C”. The input of the network performance estimation model 101b is the current values of the parameters xn_{B′C1} to xn_{B′Cn} indicating the loads of the same resources as the resources included in the network configuration graph 91 between “B′” and “C” among the resources in the second virtual network 38.

On the other hand, the container performance estimation models 102a to 102c are adopted as the container performance estimation models of “A”, “B”, and “C”, respectively. The inputs to the container performance estimation models 102a to 102c are the current values of the parameters xc_{A1} to xc_{Am}, xc_{B1} to xc_{Bm}, and xc_{C1} to xc_{Cm}, respectively.

Further, the network performance estimation models 101a and 101b are adopted as network performance estimation models between “A” and “B” and between “B” and “C”, respectively. The inputs to the network performance estimation models 101a and 101b are the current values of the parameters xn_{AB1} to xn_{ABn} and xn_{BC1} to xn_{BCn}, respectively.

Then, the estimation model 47a calculates the response time Tres_{A} of the service 43a according to the following equation (2).

Tres_{A}=t_{A}+req_{B}*t_{B}+req_{B}*t_{B′}+t_{C}+req_{B}*(t_{AB}+t_{BC})+req_{B′}*(t_{AB′}+t_{B′C}) (2)

Wherein req_{B} and req_{B′} are the values defined by the following equations (3) and (4), respectively.

req_{B}=current value of the number of requests to “B”/(current value of the number of requests to “B”+current value of the number of requests to “B′”) (3)

req_{B′}=current value of the number of requests to “B”/(current value of the number of requests to “B”+current value of the number of requests to “B”) (4)

According to this, even if the container 39 is scaled out, the response time Tres_{A} can be calculated by the network performance estimation models 101a and 101b and the container performance estimation models 102a to 102c before scale-out. As a result, when the container 39 is scaled out, the service specifying device 40 does not need to generate the new estimation model 47a, and it is possible to suppress the occurrence of the blank period in which the response time Tres_{A} cannot be estimated.

By the way, if the scale-out destination and the scale-out source of a certain container 39 are geographically separated from each other, the delay time of the network after scale-out may increase due to the geographical distance.

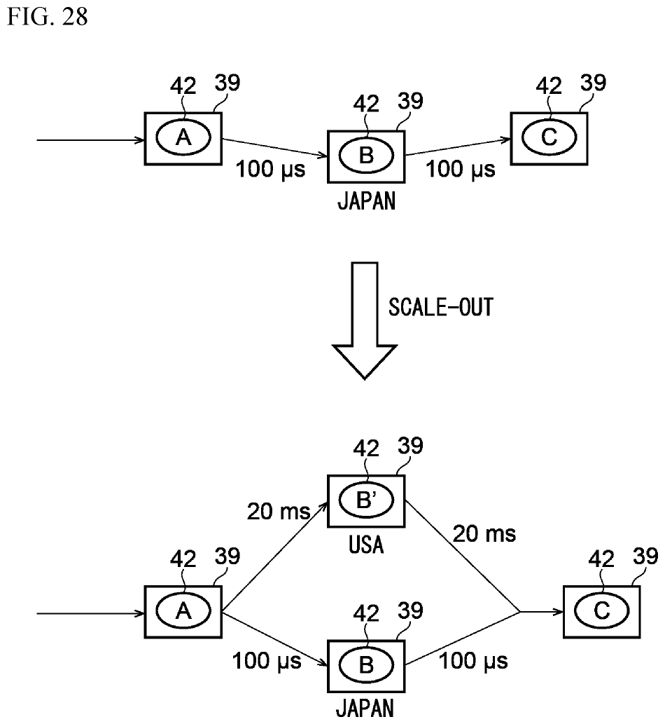

FIG. 28 is a schematic diagram in the case where the scale-out destination and the scale-out source are geographically separated from each other in this way.

It is assumed that, in the example of FIG. 28, the container 39 executing the “B” application 42 scales out from Japan to the United States, and the container 39 of the scale-out destination executes the “B” application 42.

At this time, if the delay time of the network between “A” and “B” before scale-out is 100 μsec, for example, the delay time of the network between “A” and “B′” may greatly increase to 20 msec.

In this case, if the network performance estimation model 101a between “A” and “B” is adopted as the estimation model of the network between “A” and “B”, a large error occurs in an estimation value of the delay time between “A” and “B”.

In such a case, the service specifying device 40 adds a value G to the delay time t_{AB′} of the network between “A” and “B” estimated by the network performance estimation model 101a. The value G is a value based on the geographic distance between the containers 39 executing the respective “A” and “B” applications, and is the delay time that occurs in the network between “A” and “B” due to the geographic distance. The actual measured value of the delay time measured in advance using the network may be adopted as the value G.

Thereby, even if the containers 39 executing the respective “B” and “B′” applications 42 are geographically separated from each other, the service specifying device 40 can estimate the delay time of the network between “A” and “B′” with high accuracy.

Next, the functional configuration of the service specifying device according to the present embodiment will be described.

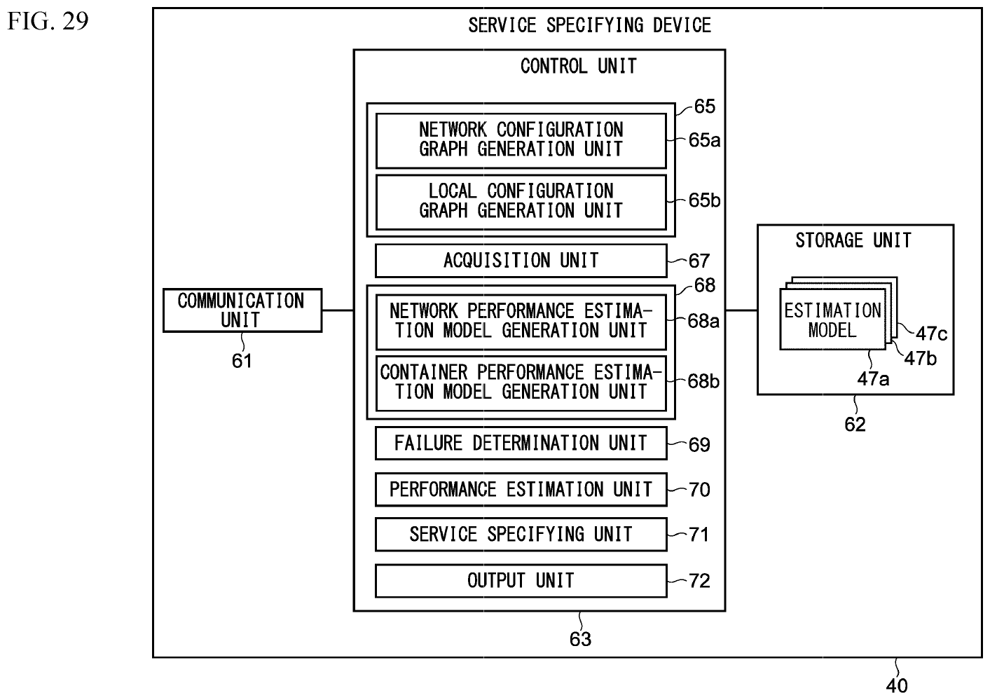

FIG. 29 is a block diagram illustrating the functional configuration of the service specifying device according to the present embodiment. In FIG. 29, the same elements as those described in the first embodiment are designated by the same reference numerals in the first embodiment, and the description thereof will be omitted below.

In the present embodiment, the graph generation unit 65 includes a network configuration graph generation unit 65a and a local configuration graph generation unit 65b, as illustrated in FIG. 29.

The network configuration graph generation unit 65a is a processing unit that generates the network configuration graph 91 (see FIG. 22). Further, the local configuration graph generation unit 65b is a processing unit that generates the local configuration graph (see FIG. 24).

Furthermore, the model generation unit 68 includes a network performance estimation model generation unit 68a and a container performance estimation model generation unit 68b.

The network performance estimation model generation unit 68a is a processing unit that generates the network performance estimation models 101a and 101b. Further, the container performance estimation model generation unit 68b is a processing unit that generates the container performance estimation models 102a to 102c.

Next, the service specifying method according to the present embodiment will be described.

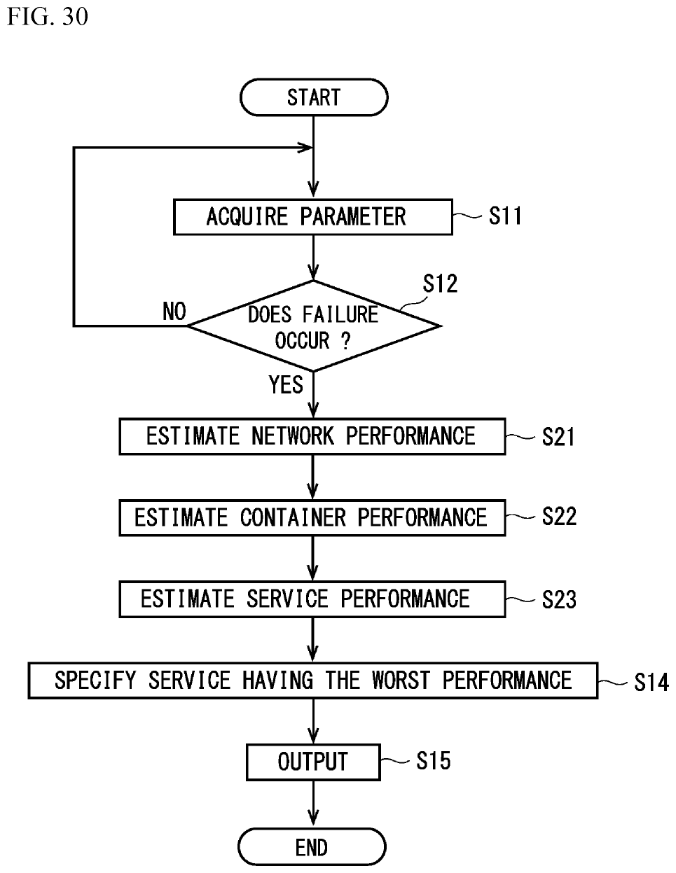

FIG. 30 is a flowchart of the service specifying method according to the present embodiment. In FIG. 30, the same steps as those in FIG. 19 of the first embodiment are designated by the same reference numerals, and the description thereof will be omitted below.

First, the acquisition unit 67 acquires the current values of the parameters x_{A1} to x_{Ap} indicating the loads of the resources used by the service 43a (step S11). In the present embodiment, the parameters xc_{A1} to xc_{Am}, xc_{B1} to xc_{Bm}, xc_{B′1} to xc_{B′m}, xc_{C1} to xc_{Cm}, xn_{AB1} to xn_{ABn}, xn_{AB′1} to xn_{AB′n}, xn_{BC1} to xn_{BCn}, xn_{B′C1} to xn_{B′Cn} illustrated in FIG. 27 become the parameters x_{A1} to x_{Ap}. Similarly, the acquisition unit 67 also acquires the current values of the parameters x_{B1} to x_{Bq} and x_{C1} to x_{Cr} indicating the loads of the resources used by the services 43b and 43c.

Next, the failure determination unit 69 determines whether the failures occur in the resources used by the services 43a to 43c based on the parameters x_{A1} to x_{Ap}, x_{B1} to x_{Bq}, and x_{C1} to x_{Cr}, respectively (step S12).

When the failure does not occur (NO in step S12), the process returns to step S11.

On the other hand, when the failure occurs, the process proceeds to step S21.

In step S21, the performance estimation unit 70 estimates the delay times t_{AB}, t_{BC}, t_{AB′}, and t_{B′C} as the network performance by using the network performance estimation models 101a and 101b.

As described with reference to FIG. 28, the container 39 of the scale-out destination that executes the “B′” application 42 might be geographically separated from the container 39 of the scale-out source that executes the “B” application 42. In this case, the performance estimation unit 70 may add, to the delay time t_{AB′} estimated by the network performance estimation model 101a, the value G which is the actual measured value of the delay time that occurs in the network between “A” and “B′” due to the geographical distance.

Next, the performance estimation unit 70 estimates the processing times t_{A}, t_{B}, t_{B′} and t_{C} as the performance of the containers 39 executing the “A”, “B”, “B′”, and “C” applications 42 (Step S22).

As an example, the performance estimation unit 70 estimates the processing time t_{A}, t_{B} and t_{C} of the respective containers 39 executing the “A”, “B” and “C” applications 42 by using the container performance estimation models 102a to 102c. For the processing time t_{B′} of the container 39 executing the “B′” application, the performance estimation unit 70 estimates it using the container performance estimation model 102b for the container 39 executing the “B” application 42 of the scale-out source.

Subsequently, the performance estimation unit 70 estimates the performance of the service 43a based on the equation (2) (step S23). In addition, the performance estimation unit 70 estimates the performance of the remaining services 43b and 43c in the same manner as the performance of the service 43a.

Next, the service specifying unit 71 specifies the service whose performance estimated in step S23 is deteriorated among the plurality of services 43a to 43c (step S14).

Subsequently, the output unit 72 outputs, to the display device 50, the instruction for displaying the service specified in step S14 on the display device 50 (step S15).

This completes the basic processing of the service specifying method according to the present embodiment.

According to the present embodiment described above, the existing container performance estimation model 102b of “B” of the scale-out source is adopted as the container performance estimation model of “B′”, as illustrated in FIG. 27. Further, the existing network performance estimation model 101a between “A” and “B” is adopted as the estimation model for estimating the delay time t_{AB′} of the network between “A” and “B”.

Thereby, even if the container 39 that executes the “B” application 42 scales out and the configuration of the infrastructure is changed, the service specifying device 40 does not need to regenerate the estimation model. As a result, in the present embodiment, even if the configuration of the infrastructure is changed, it is possible to suppress the occurrence of the blank period in which the response time cannot be estimated.

(Hardware Configuration)

Next, the hardware configuration of the physical server 32 according to the first and second embodiments will be described.

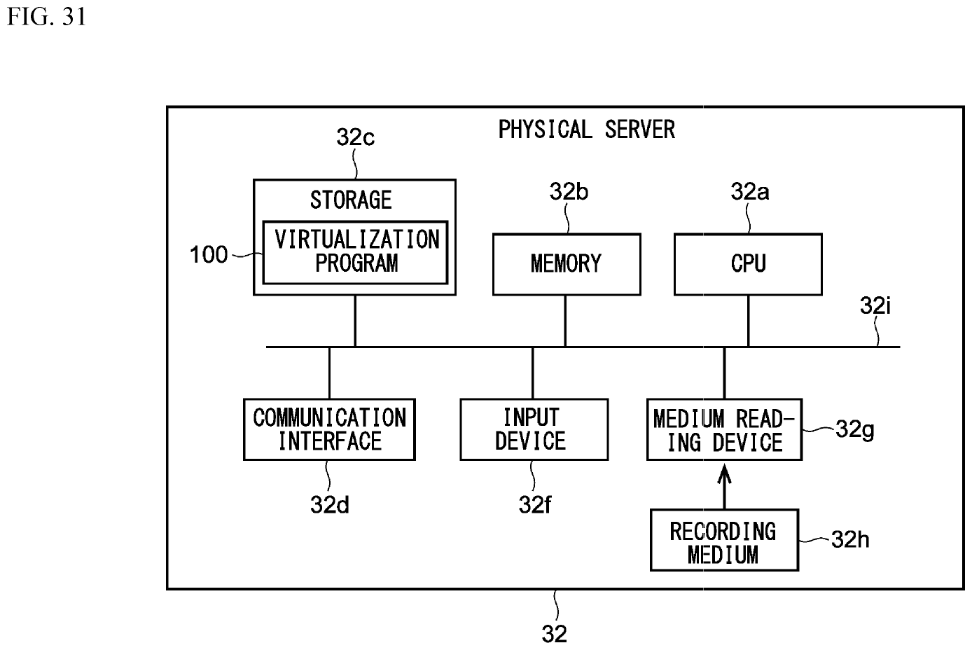

FIG. 31 is a block diagram illustrating the hardware configuration of the physical server 32 according to the first and second embodiments.

As illustrated in FIG. 31, the physical server 32 includes the CPU 32a, the memory 32b, a storage 32c, a communication interface 32d, an input device 32f and a medium reading device 32g. These elements are connected to each other by a bus 32i.

The CPU 32a is a processor that controls each element of the physical server 32. Further, the CPU 32a executes a virtualization program 100 for executing the virtual machine 37 in cooperation with the memory 32b.

Meanwhile, the memory 32b is hardware that temporarily stores data, such as a DRAM (Dynamic Random Access Memory), and the virtualization program 100 is deployed on the memory 13b.

The storage 13a is a non-volatile storage such as an HDD (Hard Disk Drive) or an SSD (Solid State Drive) that stores the virtualization program 100.

The communication interface 32d is hardware such as a NIC (Network Interface Card) for connecting the physical server 32 to the physical network 31 (see FIG. 6).

The input device 321 is hardware such as a keyboard and a mouse for the administrator of the infrastructure 45 to input various data to the physical server 32.

The medium reading device 32g is hardware such as a CD (Compact Disc) drive, a DVD (Digital Versatile Disc) drive, and a USB (Universal Serial Bus) interface for reading the recording medium 32h.

The service specifying program 41 (see FIG. 7) according to the present embodiment may be recorded on the recording medium 32h, and the first virtual CPU 37a (sec FIG. 7) may read the service specifying program 41 from the recording medium 32h via the medium reading device 32g.

Examples of such a recording medium 32h include physically portable recording media such as a CD-ROM (Compact Disc-Read Only Memory), a DVD, and a USB memory. Further, a semiconductor memory such as a flash memory, or a hard disk drive may be used as the recording medium 32h. The recording medium 32h is a computer-readable media, and is not a temporary medium such as a carrier wave having no physical form.

Further, the service specifying program 41 may be stored in a device connected to a public line, the Internet, a LAN (Local Area Network), or the like. In this case, the first virtual CPU 37a may read and execute the service specifying program 41.

In this example, one of the plurality of virtual machines 37 is the service specifying device 40 as illustrated in FIG. 7, but one of the plurality of physical servers 32 may be the service specifying device 40.

In this case, the CPU 32a and the memory 32b cooperate to execute the service specifying program 41, which can realize the service specifying device 40 having each of the functions in FIG. 14 and FIG. 29. For example, the storage unit 62 can be realized by the memory 32b and the storage 32c. Further, the communication unit 61 can be realized by the communication interface 32d. The control unit 63 can be realized by the CPU 32a.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A service specifying method for causing a computer to execute a process, the process comprising:
acquiring a parameter indicating a load of a resource used by a plurality of services for each of the plurality of services;
estimating a performance of each service for each of a plurality of the services by using an estimation model that estimates the performance of the each service from the parameter related to the each service, the estimation model being provided for each of the plurality of services; and
specifying, among the plurality of services, a service whose performance is deteriorated due to a failure of the resource based on the estimated performance.

2. The service specifying method as claimed in claim 1, the process further comprising:
outputting, to a display device, an instruction for displaying the service specified by the specifying on the display device.

3. The service specifying method as claimed in claim 1, the process further comprising:
generating the estimation model for each of the plurality of services based on learning data including the parameter of a past and an actual measured values of the performance of the past.

4. The service specifying method as claimed in claim 1, wherein
the resource is an element included in at least one of a physical server and a virtualized environment that the physical server executes.

5. The service specifying method as claimed in claim 1, wherein
the each service includes a plurality of containers connected by a network,
the estimation model has a first estimation model that estimates a container performance related to each container and a second estimation model that estimates a network performance related to the network, and
in the specifying the service, the computer specifies the service based on a total performance of the container performance and the network performance.

6. The service specifying method as claimed in claim 5, wherein
the plurality of containers include a first container, a second container, and a third container obtained by scaling out the second container, and
the computer adopts the first estimation model related to the second container as the first estimation model related to the third container, and adopt the second estimation model related to the network between the first container and the second container as the second estimation model related to the network between the first container and the third container.

7. The service specifying method as claimed in claim 6, wherein
the performance of the network between the first container and the third container is a delay time of the network, and
the computer adds a value corresponding to a geographical distance between the first container and the third container to the delay time estimated by the second estimation model.

8. A non-transitory computer-readable medium having stored therein a program for causing a computer to execute a process, the process comprising:
acquiring a parameter indicating a load of a resource used by a plurality of services for each of the plurality of services;
estimating a performance of each service for each of a plurality of the services by using an estimation model that estimates the performance of the each service from the parameter related to the each service, the estimation model being provided for each of the plurality of services; and
specifying, among the plurality of services, a service whose performance is deteriorated due to a failure of the resource based on the estimated performance.
